(19) United States
(12) Patent Application Publication
(10) Pub. No.: US 2026/0301800 A1
(43) Pub. Date: Oct. 1, 2026

(54) TECHNIQUES FOR NEAR-MEMORY COMPUTING USING HIGH-BANDWIDTH MEMORY

(71) Applicant: Neurophos Inc., Austin, TX (US)

(72) Inventors: Michael C. Shebanow, San Jose, CA (US); Donovan Popps, Austin, TX (US); Patrick T. Bowen, Austin, TX (US)

(73) Assignee: Neurophos Inc., Austin, TX (US)

(21) Appl. No.: 19/631,870

(22) Filed: Mar. 27, 2026

Related U.S. Application Data
(60) Provisional application No. 63/778,583, filed on Mar. 27, 2025.

(51) Int. Cl. G11C 11/4096; G11C 11/408; G11C 11/4093

(52) U.S. Cl. CPC G11C 11/4096; G11C 11/408; G11C 11/4093

(57) ABSTRACT

Systems and methods are described herein for high-bandwidth memory (HBM) with compute-near-memory operations. An example system includes a memory stack with multiple HBM dies connected to a base die with integrated local processing logic for designated addresses. The base die passes normal read and write commands to the HBM dies for a first subset of addresses for normal memory operations. The base die uses a second subset of addresses to route commands to the local processing logic for compute-near-memory data processing, with computed data being written directly back into the memory stack. The system reduces data movement overhead, lowers energy consumption, and achieves faster data processing.

### RELATED APPLICATION

The application claims priority under 35 U.S.C. § 119 (e) to U.S. Provisional Application No. 63/778,583, filed Mar. 27, 2025, titled “Intelligent HBM Base Die with Integrated Computer-Near-Memory Operations,” the content of which is incorporated by reference in its entirety for all purposes.

### FIELD

The techniques described herein relate generally to high-bandwidth memory architectures and high-performance computing and, more particularly, to techniques for near-memory computing using high-bandwidth memory.

### BACKGROUND

High-bandwidth memory (HBM) is a three-dimensional (3D) stacked memory architecture that enables the substantially high throughput necessary for training and running artificial intelligence (AI) models. By vertically stacking multiple dynamic random access memory (DRAM) layers and placing them in close proximity to a processor, HBM reduces data travel distances and latency. HBM can ensure that AI accelerators, such as graphics processing units (GPUs), have access to essential data during complex computational tasks.

### SUMMARY

In accordance with the disclosed subject matter, systems, apparatus, methods, and articles of manufacture are provided for near-memory computing using high-bandwidth memory (HBM).

Some embodiments relate to a system for executing compute-near-memory operations by using high-bandwidth memory (HBM). The system including a memory stack including multiple HBM dies, each HBM die including an array of banks addressable by a plurality of implemented memory addresses, wherein the plurality of implemented memory addresses includes a first subset of an available range of memory addresses, and a base die coupled to the memory stack, the base die including processor circuitry, the processor circuitry including at least one hardware processor configured to execute the compute-near-memory operations on data associated with a plurality of carveout memory addresses, wherein the plurality of carveout memory addresses includes a second subset of the available range of memory addresses. The processor circuitry is configured to receive, by using an external interface, a command referencing a memory address, retrieve, by using a memory interface configured to drive the HBM dies, the data from the memory stack for storage in first memory accessible by the at least one hardware processor when the memory address is associated with the plurality of carveout memory addresses, process, by using the at least one hardware processor, the retrieved data to generate processed data, and output the processed data.

Some embodiments relate to a base die for executing compute-near-memory operations. The base die including at least one system interface configured to receive a command referencing a memory address, at least one memory interface, and at least one hardware processor. The at least one memory interface is configured to drive at least one high-bandwidth memory (HBM) die of an HBM stack, the HBM stack addressable by a first plurality of implemented memory addresses, the first plurality of implemented memory addresses being a first portion of available memory addresses, and retrieve data from the at least one HBM die in response to a determination that the command references one of a second plurality of carveout memory addresses, the second plurality of carveout memory addresses being a second portion of the available memory addresses. The at least one hardware processor is configured to execute the compute-near-memory operations on the retrieved data to generate processed data, and output the processed data.

Some embodiments relate to a method for near-memory computing by using a memory stack including at least one high-bandwidth memory (HBM) die and a base die, the at least one HBM die associated with a plurality of memory addresses, the at least one HBM die having at least one bank addressable by a first portion of the plurality of memory addresses, the base die including at least one memory and at least one hardware processor. The method including, by using the base die, to perform receiving a command referencing a memory address, determining that the memory address references a second portion of the plurality of memory addresses, retrieving data from the at least one HBM die for storage in the at least one memory, and processing, by using the at least one hardware processor, the data to generate processed data for output to an external device.

The foregoing summary is not intended to be limiting. Moreover, various aspects of the present disclosure may be implemented alone or in combination with other aspects.

### BRIEF DESCRIPTION OF FIGURES

Various aspects and embodiments of the present technology will be described with reference to the following figures. It should be appreciated that the figures are not necessarily drawn to scale. Items appearing in multiple figures are indicated by the same or a similar reference number in all the figures in which they appear.

FIG. 1 illustrates an example computing system topology, in accordance with some embodiments of the technology described herein.

FIG. 2 illustrates an example accelerator system in communication with a host system and high-bandwidth memory (HBM) having an HBM stack architecture, in accordance with some embodiments of the technology described herein.

FIG. 3 illustrates an example implementation of the HBM stack architecture of FIG. 2, in accordance with some embodiments of the technology described herein.

FIG. 4A illustrates an example microbump topology, in accordance with some embodiments of the technology described herein.

FIG. 4B shows a table of a number of possible through-silicon via (TSV) pins and signal density based on TSV density, in accordance with some embodiments of the technology described herein.

FIG. 5 illustrates a simplified diagram of an example electrical model for HBM, in accordance with some embodiments of the technology described herein.

FIG. 6 illustrates a block diagram of an example implementation of an intelligent base die processing system for HBM, in accordance with some embodiments of the technology described herein.

FIG. 7 illustrates an example implementation of a processor block of the intelligent base die processing system of FIG. 6, in accordance with some embodiments of the technology described herein.

FIG. 8 illustrates an example of a master command register (MCR), in accordance with some embodiments of the technology described herein.

FIG. 9 illustrates a table of four example MCR commands, in accordance with some embodiments of the technology described herein.

FIG. 10 illustrates an example encoding format for the SBDBAR MCR command of FIG. 9, in accordance with some embodiments of the technology described herein.

FIG. 11 illustrates an example encoding format for the set interrupt queue command of FIG. 9, in accordance with some embodiments of the technology described herein.

FIG. 12 illustrates an example encoding format for the read “N” entries command of FIG. 9, in accordance with some embodiments of the technology described herein.

FIG. 13 illustrates an example encoding format for the execute command of FIG. 9, in accordance with some embodiments of the technology described herein.

FIG. 14 illustrates an example implementation of a set interrupt queue entry, in accordance with some embodiments of the technology described herein.

FIG. 15 illustrates an example implementation of a circular first-in-first-out (FIFO) interrupt queue, in accordance with some embodiments of the technology described herein.

FIG. 16 illustrates an example memory layout of an interrupt queue (IQUEUE), in accordance with some embodiments of the technology described herein.

FIG. 17 illustrates example pseudocode of an algorithm for inserting requests into the queue, in accordance with some embodiments of the technology described herein.

FIG. 18 illustrates example pseudocode of an algorithm for pseudo-channel request queue servicing, in accordance with some embodiments of the technology described herein.

FIG. 19 illustrates an example bank configuration within an HBM pseudo channel, in accordance with some embodiments of the technology described herein.

FIG. 20 illustrates an example data flow from a producer node to a consumer node, in accordance with some embodiments of the technology described herein.

FIG. 21 illustrates a diagram of an example data transform expansion flow, in accordance with some embodiments of the technology described herein.

FIG. 22 illustrates a diagram of an example data transform contraction flow, in accordance with some embodiments of the technology described herein.

FIG. 23 illustrates a diagram of an example cache-cache transform flow, in accordance with some embodiments of the technology described herein.

FIG. 24 illustrates an example of a pitch layout for a two-dimensional tensor, in accordance with some embodiments of the technology described herein.

FIG. 25 illustrates an example of a block linear layout, in accordance with some embodiments of the technology described herein.

FIG. 26 is an example of a tiled matrix layout, in accordance with some embodiments of the technology described herein.

FIG. 27 illustrates an example simplified performance model of each HBM pseudo channel, in accordance with some embodiments of the technology described herein.

FIGS. 28A-D show a table of Open Neural Network Exchange (ONNX) operators that may be implemented, in accordance with some embodiments of the technology described herein.

FIG. 29 illustrates a block diagram of another example implementation of an intelligent base die processing system for HBM, according to one example architecture.

FIG. 30 illustrates an example channel block architecture, in accordance with some embodiments of the technology described herein.

FIG. 31 illustrates an example processor block architecture, in accordance with some embodiments of the technology described herein.

FIG. 32 is a flowchart representative of an example process that may be performed and/or implemented using (i) hardware logic or (ii) machine-readable instructions that may be executed by processor circuitry to implement the intelligent base die processing system for HBM of FIGS. 6 and/or 29 to execute near-memory computing, in accordance with some embodiments of the technology described herein.

FIG. 33 is an example electronic platform structured to implement the hardware logic and/or execute the machine-readable instructions of FIG. 32 to implement the intelligent base die processing system for HBM of FIGS. 6 and/or 29, in accordance with some embodiments of the technology described herein.

### DETAILED DESCRIPTION

The present disclosure provides techniques for near-memory computing using high-bandwidth memory (HBM). In some embodiments, a system (e.g., a system architecture) includes a memory stack with multiple HBM dies connected to a base die. The base die can include integrated local processing logic. The integrated local processing logic can be configured to execute compute operations associated with designated carveout memory addresses, as described in greater detail herein. In some embodiments, the base die passes normal read and write commands associated with a first subset of a plurality of memory addresses to the HBM dies for normal memory operations. The base die can use a second subset of the plurality of memory addresses as carveout memory addresses to route commands to the local processing logic for compute-near-memory data processing. The locally computed data can be written directly back into the memory stack. Additionally and/or alternatively, the locally computed data may be output to an accelerator die. In contrast to conventional approaches that do not perform local processing of data retrieved from the HBM on the base die, the example compute-near-memory HBM architectures described herein reduce data movement overhead, lower energy consumption, and achieve faster data processing and increased overall system bandwidth. Moreover, the use of a carveout set of memory addresses enables both conventional interfacing and enhanced compute-near-memory controls without any additional or customized external interfacing.

Some conventional systems include a host system, an accelerator, and a memory stack. The memory stack can include HBM dies stacked on top of a base die. In conventional operation, the host system can issue a data request (e.g., a read, a write) to the accelerator, specifying a memory address in the HBM stack. The accelerator can receive the data request and invoke its memory controller to issue a read command carrying the memory address to the HBM stack. The read command can be issued to the HBM stack to retrieve data at the memory address from the HBM stack. The HBM stack may output data corresponding to the memory address to the accelerator. The accelerator may return the retrieved data (or a processed version thereof) to the host system.

The inventors have recognized multiple technological challenges with such conventional systems. First, transferring data from the HBM stack to the accelerator for processing increases data movement overhead. For example, the data must be transferred from the HBM stack, to the accelerator via the base die in order to enable the accelerator to process the data. Each data transferring step incurs data movement overhead.

Second, processing the retrieved data from the HBM stack on the accelerator increases overall energy consumption. For example, the base die consumes power when processing the read command, retrieving data from the HBM stack, and transferring the retrieved data to the accelerator. The accelerator further consumes power to process the retrieved data.

Third, processing data on the accelerator may incur increased latency. For example, in such conventional systems, the data processing is delayed until the accelerator receives the data from the base die.

Fourth, processing data on the accelerator reduces overall system bandwidth. For example, the computational bandwidth for such conventional systems is limited to the accelerator shoreline. An accelerator shoreline refers to a physical perimeter or an edge area of an accelerator die where data connections can be placed to connect to other chips or devices, such as the base die of the HBM stack. Examples of the data connections include bumps and Input/Output (I/O) pins. The number of connections at the shoreline may be referred to as “shoreline bandwidth density.” Shoreline bandwidth density may be measured in gigabits per second per millimeter (Gbps/mm) or the number of pins per unit length.

The inventors have recognized that the accelerator shoreline becomes a bottleneck in conventional systems. For example, in some conventional systems, the physical constraints of the accelerator shoreline limits the number of data connections between the accelerator and the base die and, thus, limits the quantity of data that can be exchanged across the accelerator-base die physical interface.

The inventors have developed technology that overcome the aforementioned technological challenges. The technology developed by the inventors includes an accelerated computing system, which may include an accelerator coupled to a memory stack. The accelerated computing system may be a heterogeneous computing platform in which a host system delegates heavy data-processing tasks to the accelerator that is tightly coupled with high-speed HBM. The host system may be a host processor, such as a centralized processing unit (CPU). The accelerated computing system may implement and/or correspond to an Open Accelerator Module (OAM) at least in part.

The memory stack may be an HBM stack including multiple HBM dies connected to a base die. The multiple HBM dies can be connected to the base die via one or more sets of data connections (e.g., through-silicon vias (TSVs)) in a vertical direction to increase shoreline bandwidth density. The base die can include integrated local processing logic for designated carveout memory addresses. The base die can be configured effectuate conventional interfacing by routing commands (e.g., read commands, write commands) to the HBM dies when the commands are associated with a first subset of a plurality of memory addresses. The base die can be configured to effectuate compute-near-memory operations by routing commands to the local processing logic when the commands are associated with a second subset of the plurality of memory addresses. The second subset of the plurality of memory addresses can be carveout memory addresses. The locally computed data can be written directly back into the memory stack. Additionally and/or alternatively, the locally computed data may be output to the accelerator for further processing and/or routing to the host system.

Beneficially, the technology developed by the inventors solves the aforementioned technological challenges. First, the HBM stack can reduce data movement overhead. For example, the base die can locally process data associated with the carveout addresses instead of transferring the data to the accelerator for processing. Second, by locally processing data associated with carveout addresses, the HBM stack can reduce overall energy consumption by reducing data movement between the HBM stack and the accelerator and reducing the accelerator's workload.

Third, the HBM stack can decrease system latency by locally processing carveout address related data instead of transferring the data from the HBM stack to the accelerator for processing. Fourth, the HBM stack can be configured to have increased shoreline bandwidth density with respect to conventional memory stacks by including multiple sets of data connections spanning a vertical direction of the HBM stack.

The techniques described herein may be implemented in any of numerous ways, as the techniques are not limited to any particular manner of implementation. Examples of details of implementation are provided herein solely for illustrative purposes. Furthermore, the techniques disclosed herein may be used individually or in any suitable combination, as aspects of the technology described herein are not limited to the use of any particular technique or combination of techniques.

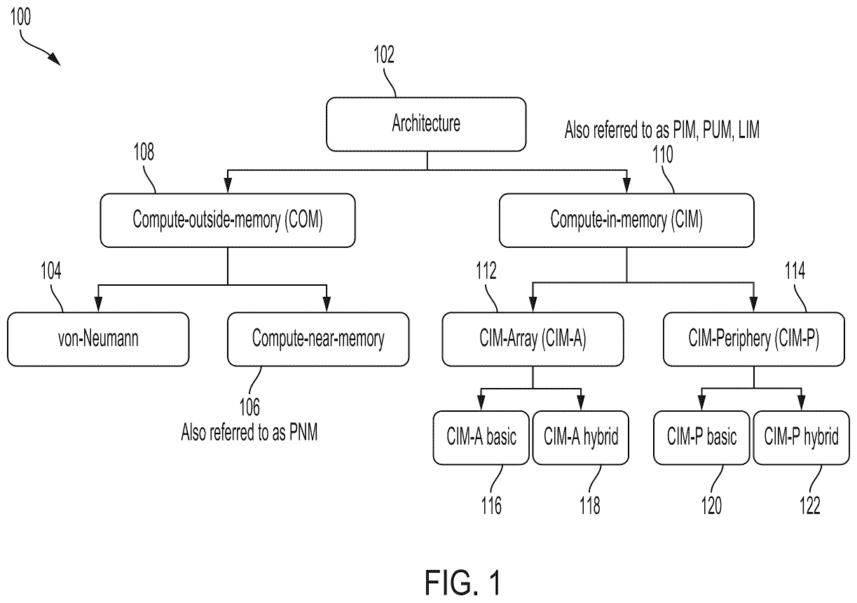

FIG. 1 illustrates an example computing system topology 100 in accordance with an architecture 102. The architecture 102 may be implemented in a number of ways as shown. The computing system topology 100 may be in accordance with “The Landscape of Compute-near-Memory and Compute-in-Memory: A Research and Commercial Overview” by Khan, Asif Ali, et al., 2024.

At the far lower left, traditional computing systems are classified as “von-Neumann” 104. To the right is “Compute Near Memory” (CNM) 106, which refers to processing done closer to memory storage devices but not inside these devices. Both traditional von-Neumann computing systems 104 and CNM computing 106 may be collectively classified as “Compute-outside-memory” (COM) 108. Alternatively, computing systems may perform computations directly in memory devices, which are classified as “Compute-in-memory” (CIM) systems 110. As shown, these CIM systems 110 can be further broken down into “CIM-Array” (CIM-A) computing 112 and “CIM-Periphery” (CIM-P) computing 114. CIM-A systems 112 perform computation in an array of bit cells forming the memory, while CIM-P systems 114 perform computation at the peripheral boundaries of these arrays. CIM-A systems 112 may be further classified into “CIM-A basic” systems 116 and “CIM-A hybrid” systems 118. CIM-P systems 114 may be further classified into “CIM-P basic” systems 120 and “CIM-P hybrid” systems 122.

In some embodiments, the presently described systems, methods, and architectures may pertain to CNM processing in high-bandwidth memory (HBM) devices. For example, the presently described systems, methods, and architectures may be used in conjunction with HBM3, HBM4, and subsequent revisions to the Joint Electron Device Engineering Council (JEDEC) JESD238A specification with reference to “High Bandwidth Memory DRAM (HBM3)”, JEDEC standard JESD238A, January 2023.

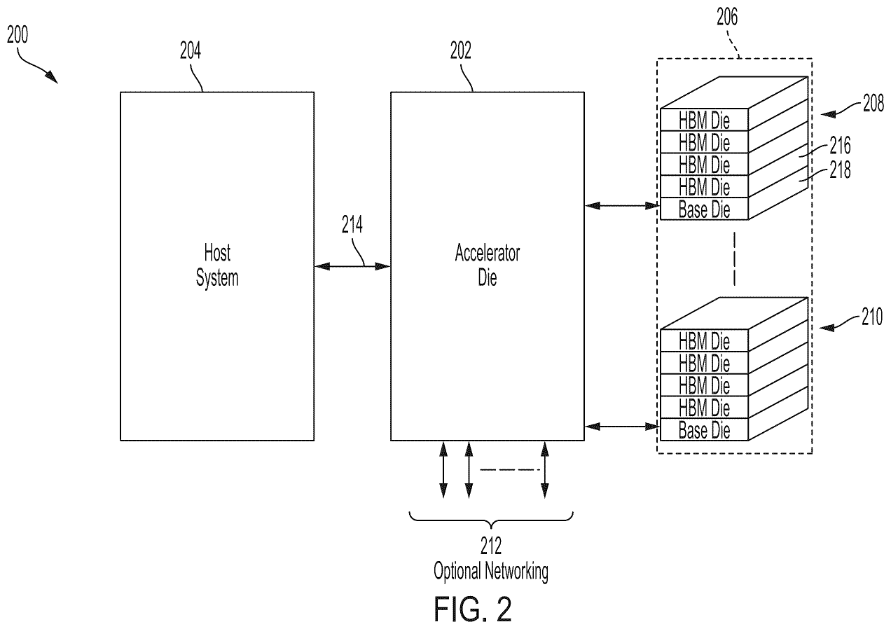

FIG. 2 illustrates an example accelerated computing system 200. The accelerated computing system 200 includes an accelerator system (“accelerator”) 202 in communication with a host system 204 and HBM 206. The HBM 206 may include one or more HBM stacks. By way of example, FIG. 2 includes at least a first HBM stack 208 and a second HBM stack 210. Alternatively, the accelerated computing system 200 of FIG. 2 may be implemented by using a single HBM stack. The accelerated computing system 200 may be a heterogeneous computing platform in which the host system 204 delegates heavy data-processing tasks, such as artificial intelligence and/or machine learning (AI/ML) workloads, to the accelerator 202 that is tightly coupled with the HBM 206. In some embodiments, as described herein, the presently described systems, methods, and architectures can interface directly with the host system 204, the accelerator 202, or an external computing system or network. The accelerator 202 may, for example, be an artificial intelligence (AI) and/or machine learning (ML) accelerator configured to specifically accelerate operations associated with AI computations. The accelerator system 202 can be an external accelerator system to the HBM 206, and the external accelerator system can include at least one accelerator die.

In some embodiments, the accelerated computing system 200 may be and/or implement an Open Accelerator Module (OAM) at least in part. For example, the host system 204, the accelerator 202, and the HBM 206 may be part of the same baseboard system that is configured to support high-bandwidth communication between modules for demanding workloads. In such an example, the host system 204, the accelerator 202, and the HBM 206 may be on the same printed circuit board (PCB) or included in the same PCB assembly that includes two or more PCBs. The PCB may implement an expansion board (e.g., a mezzanine card, a daughterboard) configured to be plugged into a compatible connector on a larger PCB (e.g., a host carrier board, such as the Universal Baseboard or UBB). Alternatively, the host system 204 may be separate from the accelerator 202 and the HBM 206 such that the host system 204 is implemented by one or more first PCBs different than one or more second PCBs that may implement the accelerator 202 and the HBM 206.

The host system 204 may be implemented by at least one programmable processor configured to execute a host operating system (e.g., a Linux-based computing device). The host system 204 can be an external host to the accelerator 202 and the HBM 206. The at least one programmable processor may be at least one CPU. The accelerator 202 may be an AI/ML accelerator. By way of example, the host operating system of the host system 204 may communicate with the AI/ML accelerator through an interface 214. An example of the interface 214 is a Peripheral Component Interconnect Express (PCIe) interface. The accelerator 202 can be configured to interface with at least the first HBM stack 208 and the second HBM stack 210, each of which may include multiple HBM dies 216 stacked on a base die 218. Although only four of the HBM dies 216 are shown in each of the first HBM stack 208 and the second HBM stack 210, one(s) of the HBM stacks 208, 210 in the HBM 206 may be implemented with a different number of dies. For example, one(s) of the HBM stacks 208, 210 in the HBM 206 may be respectively implemented by a number of dies in a range of 4-16 dies.

The base die 218 can be configured to mediate data between the accelerator 202 and the HBM dies 216. In some embodiments, networking interfaces 212 can be configured to enable out-of-band communication directly with the accelerator 202 without involving the host system 204. Examples of the networking interfaces 212 include PCIe and Ethernet. Although FIG. 2 illustrates the accelerator 202 implemented by a single accelerator die, multiple accelerators can be integrated using chiplets in advanced packaging.

Beneficially, as disclosed herein, the base die 218 of each of the HBM stacks 208, 210 can be configured to execute memory and compute-near-memory operations utilizing unimplemented memory addresses. Although most of the examples disclosed herein are provided in the context of HBM (e.g., HBM3 and HBM4), the present disclosure can be implemented in the context of other memory types, such as dynamic random-access memory (DRAM), static random-access memory (SRAM), and the like.

HBM3 and earlier memory architectures have a 1024-bit interface composed of 16 channels that are each 64-bit wide. HBM4 introduces a 2048-bit interface with 32 channels that are each 64-bit wide. Each channel can be divided into two pseudo channels that are 32 bits wide each. Like Double Data Rate (DDR) memory, data is clocked on both edges, achieving speeds up to 9.7 gigabits per second (Gb/s) for High Bandwidth Memory 3E (HBM3E) and initially 6.4 Gb/s for HBM4. According to the JEDEC JESD238A standard, HBM dies can be stacked into configurations of 4, 8, 12, or 16 layers. Future standards may allow for larger configurations.

In some embodiments, the bandwidth of the HBM dies 216 into the base die 218 matches and/or substantially matches the bandwidth between the base die 218 and an attached processor, such as the accelerator 202 in this example. In some embodiments, the bandwidth may be limited due to the density limitations of the through-silicon vias (TSVs) of the HBM stacks 208, 210. Future generations of HBM might include architectures or specifications that relax these limitations. For example, as disclosed herein, the bandwidth from the HBM dies 216 to the base die 218 may increase relative to the bandwidth from the base die 218 to the accelerator 202. In addition, future DRAM technology may permit a three-dimensional (3D) package structure where the HBM dies 216 and their base die 218 are directly connected to the accelerator die 202. Assuming bump pitch is improved in both the HBM dies 216 and the base die 218, this may further increase the bandwidth available to the accelerator 202 or the base die 218. Beneficially, as disclosed herein, the HBM stacks 208, 210 may include a plurality of sets of TSVs connecting the HBM dies 216 and the base die 218 to increase shoreline density and thereby increase bandwidth between the HBM dies 216 and the base die 218 to meet future architectures or specifications that relax the above noted limitations.

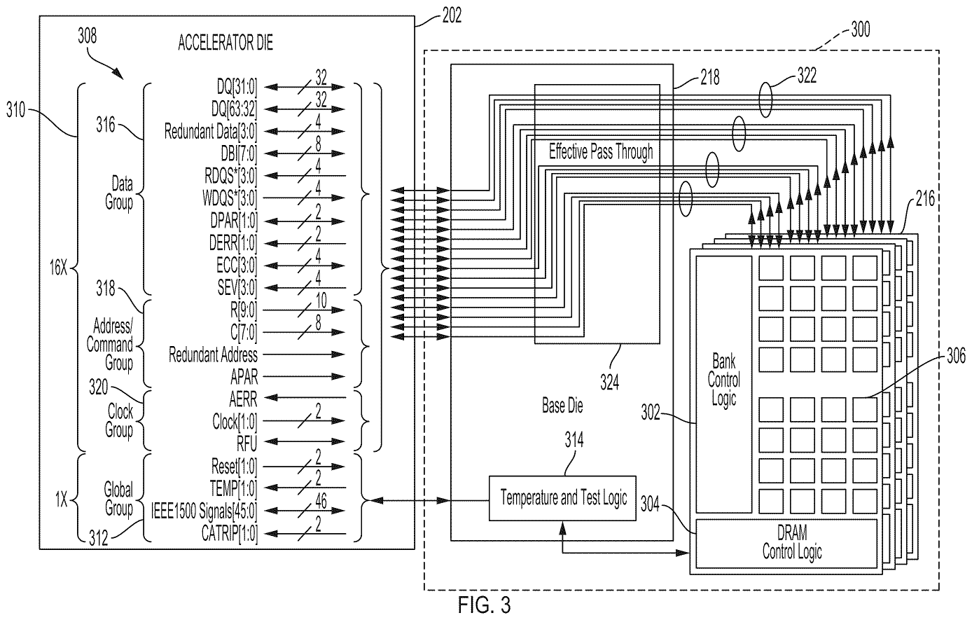

FIG. 3 illustrates an example of an HBM stack architecture 300 electrically and communicatively coupled to the accelerator 202 of FIG. 2. The HBM stack architecture 300 of this example is a 4-high HBM stack and associated DRAM. In some embodiments, the HBM stack architecture 300 may implement the first HBM stack 208 or the second HBM stack 210 of FIG. 2. In some such embodiments, the HBM stack architecture 300 may include the HBM dies 216 and the base die 218 of FIG. 2. Each of the HBM dies 216 may include bank control logic 302, memory control logic 304, and memory banks 306. The memory control logic 304 may be DRAM control logic. The memory banks 306 may be DRAM banks (e.g., banks of DRAM).

As illustrated, the left edge includes a breakout of HBM signals 308. The HBM signals 308 of this example are HBM3 signals. Alternatively, the HBM signals 308 may be different HBM signals, such as HBM3E or HBM4 signals. The HBM stack architecture 300 of this example features 16 channels 310 and one global group 312. The global group 312 are global group signals and encompasses a total of 52 signals. The global group 312 is connected to temperature and test logic 314 of the base die 218, which subsequently links to all of the HBM dies 216 within the HBM stack (e.g., the HBM stack 208, 210 of FIG. 2). Each of the 16 channels 310 includes a data group 316, an address/command group 318, and a clock group 320, amounting to 120 signals in total for each of the 16 channels 310. The signals from the 16 channels 310 and the global group 312 are routed to the base die 218.

In some embodiments, the channels 310 are organized into groups 322 of four channels each, with each of the groups 322 being routed to one of the HBM dies 216 or sets of the HBM dies 216 within the HBM stack (e.g., the four HBM dies 216). Alternatively, the channels 310 may be organized into different sized groups than shown and/or may be routed differently than shown.

As shown, the HBM dies 216 are depicted with a maximum number of banks, 16 per pseudo channel per channel. In some embodiments, each of the banks 306 operates independently, allowing a controller to initiate simultaneous access to these banks 306 through overlapped activate commands, subject to the overall DRAM IDD current limits. DRAM IDD current may refer to the amount of supply current flowing to the positive power supply input for an integrated circuit (e.g., the VDD pin). In some embodiments, data transfers from pages within each bank are serialized within each pseudo channel. In some embodiments, HBM accesses are executed in 32-byte blocks per pseudo channel.

The fundamental operation of an HBM die (e.g., an HBM DRAM) aligns with that of conventional DRAMs. Banks are organized into pairs of “half banks” per pseudo channel, each including rows and columns of bit cells. In HBM3, the maximum configuration per half bank includes 32,768 rows by 32 column groups by 256 bits per column group, amounting to 32 Mebibytes (MiB) per half bank. Each half bank contains its own row buffer, which stores a 1 kibibyte (KiB) “page.” To access memory within a half bank for either reading or writing, the bank is first “activated,” which destructively reads a row into the row buffer. Thereafter, read and write operations can selectively access 256 bits at a time within the row buffer through column commands. The row buffer is “closed” via a “precharge” command to transition to a new page, thereby writing back the old (and possibly modified) row buffer to the row that was initially destroyed.

Some embodiments systems may utilize a “non-intelligent” or “dumb” base die configuration. In such a configuration of some such conventional systems, the channels 310 are transmitted directly to the HBM dies 216 via an effective pass through 324. However, such configurations increase data movement overhead, increase energy consumption, decrease data processing speed, and decrease overall system bandwidth. Beneficially, the present disclosure improves upon such non-intelligent or dumb base die configurations by providing an intelligent HBM base with integrated computer-near memory operations capabilities. Such an intelligent HBM base die may include integrated local processing logic that can locally process data on the base die 218 that is retrieved from the HBM dies 216 when memory commands are received from the accelerator die 202 that reference carveout memory addresses as described further herein. Additionally, in some embodiments, the accelerator 202 can include a memory controller (not shown) separate from the base die 218 such that the base die 218 can selectively pass memory commands from the external memory controller to the HBM stacks 208, 210.

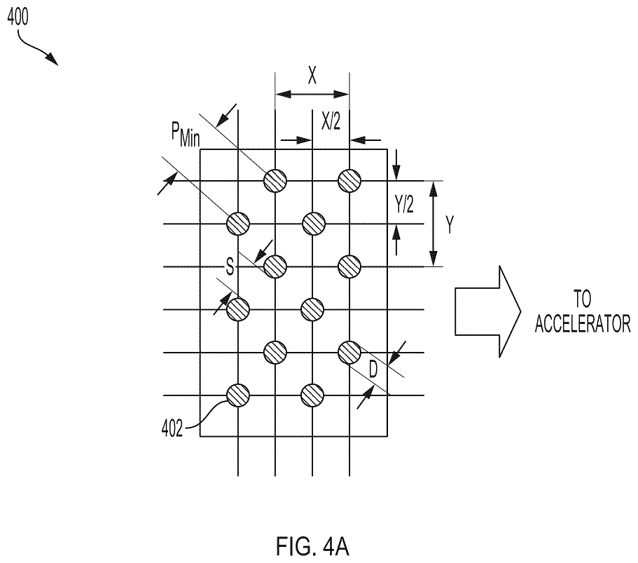

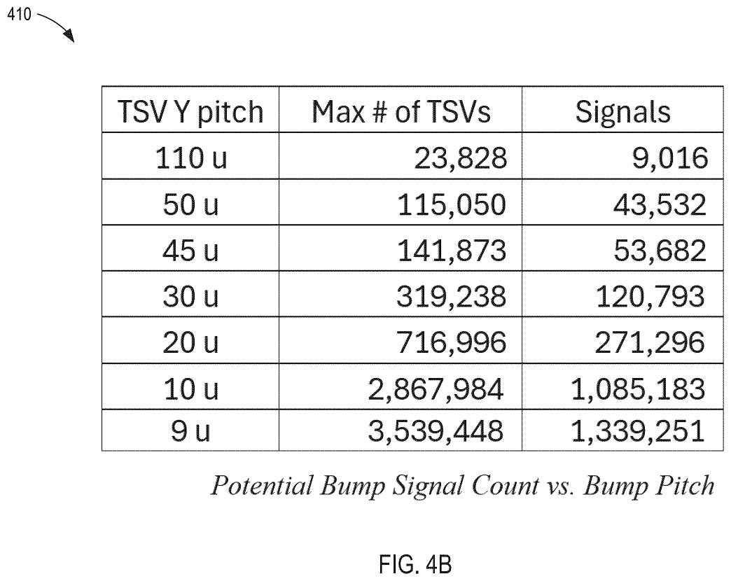

FIG. 4A illustrates an example microbump topology 400. The microbump topology 400 includes a plurality of microbumps 402. In some embodiments, each of the HBM dies 216 of FIGS. 2 and/or 3 may be implemented at least in part by the microbump topology 400.

In some embodiments, the microbump topology 400 is implemented according to the HBM3 specification. An HBM die, such as one of the HBM dies 216 of FIGS. 2 and/or 3, may, for example, measure 10.975 millimeters (mm) by 10.975 mm. In some embodiments, the signal connectivity is limited by the density of TSVs.

As illustrated, the microbump topology 400 includes a microbump pattern where “X” is a horizontal pitch of 96 micrometers or microns (μm), “Y” is a vertical pitch of 110 μm, “PMin” is 73 μm diagonally, and “D” is a microbump diameter of 28 μm. The HBM die footprint (e.g., the footprint of one of the HBM dies 216) can have 161 rows at Y/2 pitch and 148 columns at X/2 pitch, making the overall array size 7084.0 μm by 8828.0 μm. This results in 23,828 microbumps, with approximately 38% used for signaling. For example, the HBM dies 216 may each include 23,828 microbumps.

FIG. 4B shows a table 410 with the number of possible TSV pins based on TSV density scaled to the HBM3 specification and signal density. The “Max #of TSVs” column shows the highest TSV count in the 7084.0 μm by 8828.0 μm area. The “Signals” column lists TSV counts based on a 37.8% signal budget (matching the HBM3 allocation). HBM3 uses 1,972 TSVs for signals, while HBM4 uses approximately 3,892 TSVs. Not all of the area allocated for signals is employed for signals, and the table is merely an example of one possible example of how bump counts could increase with denser bump pitches.

The inventors have recognized that future advancements in the process and packaging of HBM dies are likely to increase the signal count from the base die to the HBM die(s). The present disclosure takes advantage of the existing bandwidth between the base die and the HBM die(s) and can readily utilize any potential increase in bandwidth to provide on-base-die computation.

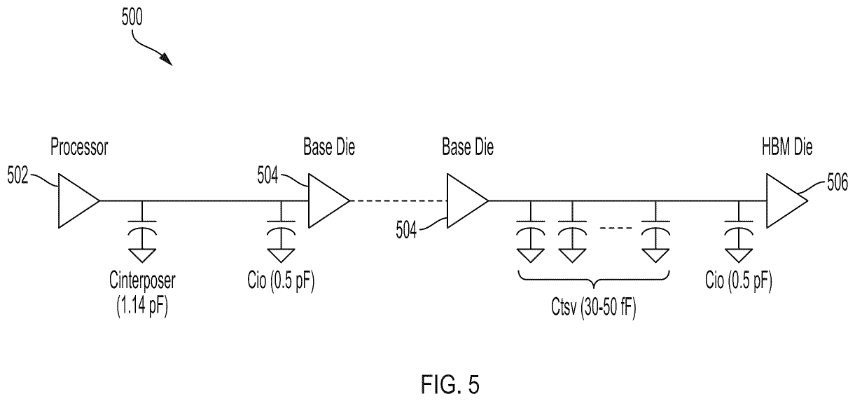

FIG. 5 illustrates a simplified diagram of an example electrical model 500 for HBM. The electrical model 500 includes a processor 502, a base die 504, and an HBM die 506. In some embodiments, the processor 502, the base die 504, and the HBM die 506 of FIG. 5 may correspond to the accelerator 202, the base die 218, and the HBM dies 216 of FIG. 2, respectively.

In some embodiments, an estimate of TSV electrical properties can be made based on the following assumptions: (i) the TSV diameter (e.g., a diameter in the 5-10 μm range for HBM), (ii) the dielectric thickness (e.g., 0.2-0.5 μm thickness of oxide or another insulator), and (iii) the TSV height (depth) (e.g., tens of micrometers, such as a height in a range of 40-100 μm, depending on the stack height). The capacitance per TSV per layer can be estimated at between 30 and 50 femtofarads (fF).

As illustrated in the simplified diagram of FIG. 5, a processor 502 can be configured to drive its HBM interface to a base die 504 through an interposer (e.g., in the case of advanced packaging). For example, some conventionally available advanced packaging features can have approximately 0.2 fF per micron in linear capacitance. Given the HBM die width of approximately 11 mm (or 11,000 microns), and assuming a signal must traverse half the width of the HBM die plus some margin, there is an estimated approximately 5,700 microns per signal or 1,140 fF per signal. With the maximal input capacitance of the base die being 0.5 pF, the net signal capacitance is estimated at approximately 1.64 picofarads (pF).

In comparison, on the right side of the diagram, where the base die 504 drives up to 12 layers of an HBM die 506, assuming an average traversal of 10 layers, the capacitance is estimated at 300-500 fF per base die TSV contact. Coupled with an average maximum input capacitance of the HBM die 506 of 0.5 pF, the total capacitance is 0.9 pF. When comparing wire energy between computing on the base die, and the main processor die (assuming equal voltage swings), there is a power gain of 2.82× in signal power. The rough estimates and calculations provided above are for illustration purposes only to show the relative capacitances and power differences. The actional values are contingent upon various parameters related to both process and design.

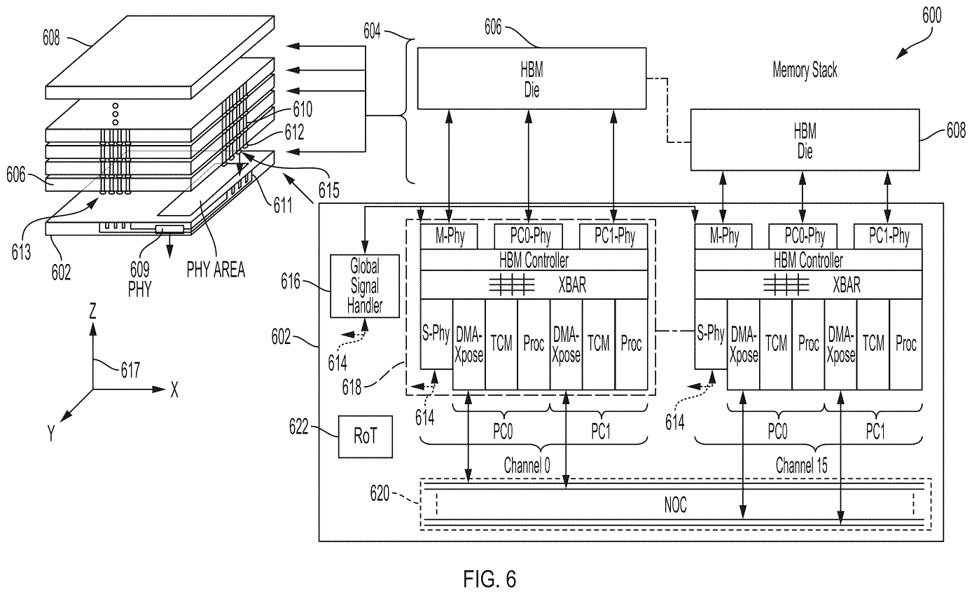

FIG. 6 illustrates a block diagram of an example implementation of an intelligent base die processing system 600 for HBM. The intelligent base die processing system 600 can be a CNM system. The intelligent base die processing system 600 includes a base die 602 connected to a memory stack 604. The base die 602 can be an HBM base die. The base die 602 can be an intelligent base die (e.g., an intelligent HBM base die).

As illustrated, the memory stack 604 includes of a plurality of HBM dies 606, 608, which include at least a first HBM die 606 and a second HBM die 608. The plurality of HBM dies 606, 608 of this example include 16 HBM dies. Alternatively, the memory stack 604 may be implemented by a different number of dies, such as a number of dies in a range of 2-15 dies.

As an example and as shown inset in FIG. 6, the HBM dies 606, 608 may be connected to the base die 602 with TSVs 610 and microbumps 612. The base die 602 may be connected to an external processor (e.g., the accelerator 202 of FIG. 2) via a logic base physical interface (PHY) 609. The logic base physical interface 609 can be connected to a logic base physical interface of an external processor (not shown) via an interposer (not shown). The TSVs 610 can be arranged in the HBM dies 606, 608 such that the microbumps 612 are aligned to corresponding connecting portions 611 of the logic base physical interface 609 to establish electrical connectivity. For example, the connecting portions 611 can be data connections configured to mate with the microbumps 612 to establish electrical and/or communicative connectivity.

The HBM dies 606, 608 of this example include multiple sets of data connections 613, 615, such as multiple sets of the TSVs 610 and the microbumps 612, to increase shoreline density in a vertical direction of the memory stack 604. The vertical direction is shown in FIG. 6 as a Z-direction in Cartesian coordinate system 617. The planar directions of the memory stack 604 are shown in FIG. 6 as X- and Y-directions in the Cartesian coordinate system 617.

The sets of data connections 613, 615 include a first set of data connections 613 and a second set of data connections 615. The first set of data connections 613 are integrated and/or otherwise disposed on a first side of the HBM dies 606, 608. The second set of data connections 615 are integrated and/or otherwise on a second side of the HBM dies 606, 608, different from the first side. Alternatively, the sets of data connections 613, 615 may be integrated and/or otherwise disposed elsewhere on the HBM dies 606, 608 than shown, such as integrated in the interior or inner locations of the HBM dies 606, 608. For example, the TSVs 610 can include the first set of data connections 613 disposed in respective first areas of the HBM dies 606, 608 and the second set of data connections 615 disposed in respective second areas of the HBMM dies 606, 608, different from the first areas. Although not shown, the HBM dies 606, 608 may include additional sets of data connections. Alternatively, the HBM dies 606, 608 may not include the first set of data connections 613 or the second set of data connections 615.

Beneficially, the multiple sets of data connections 613, 615 can increase shoreline bandwidth density by increasing the number of data connections between the HBM dies 606, 608 and the base die 602. Beneficially, by increasing the number of data connections between the HBM dies 606, 608 and the base die 602, the bandwidth between the HBM dies 216 and the base die 218 is correspondingly increased to meet future architectures or specifications.

HBM signals 614 can link to an external processor (e.g., the accelerator 202 of FIG. 2). The HBM signals 614 may be configured according to, for example, the JEDEC standards. In some embodiments, the HBM signals 614 may correspond to the signals in the global group 312 of FIG. 3. In some embodiments, the HBM signals 614 are temperature and test signals. Examples of the temperature and test signals include signals representative of and/or indicative of temperature measurements, results of built-in self-tests (BISTs), results of error correction operations, and results of thermal tests.

As illustrated, the base die 602 includes a global signal handler 616, a processor block 618, and a network-on-chip (NOC) 620. In some embodiments, the global signal handler 616 is global signal handler circuitry configured to manage temperature and device testing. For example, the global signal handler 616 can implement and/or correspond to the temperature and test logic 314 of FIG. 3. In such an example, the global signal handler 616 can receive the HBM signals 614 from the accelerator 202.

In some embodiments, the global signal handler 616 is global signal handler circuitry configured to receive and/or transmit global signals, such as at least one signal from the global group 312 of FIG. 3. For example, the global signal handler 616 can generate the reserved encoding of TEMP[1:0] encoding (“10”) as an interrupt signal. In such an example, the TEMP[1:0] signal lines can be repurposed as an interrupt mechanism to indicate to the accelerator 202 completion of compute operations on the base die 602, such that processed data generated by the base die 602 is ready for consumption by the accelerator 202. For example, the global signal handler 616 can generate the reserved encoding of TEMP[1:0] to implement an interrupt mechanism configured to notify a system physical interface 716 that the processor 710 has completed a compute-near-memory operation. In such an example, the interrupt mechanism includes repurposed reserved bits of an HBM signal specification (e.g., the reserved bits of TEMP[1:0].

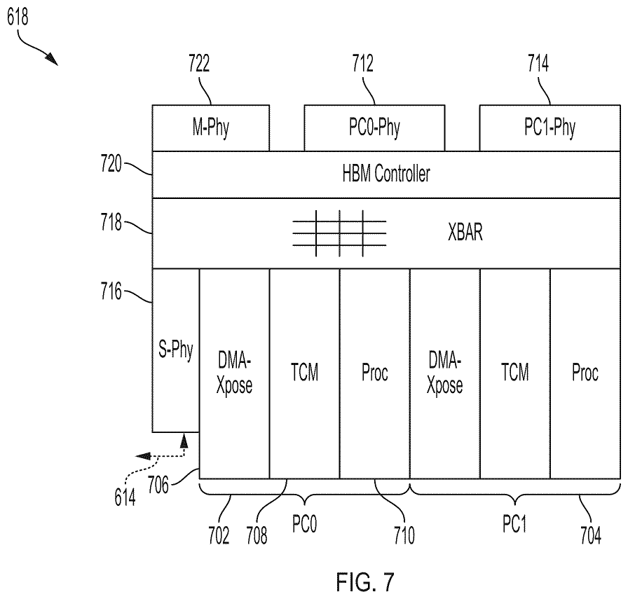

In some embodiments, the processor block 618 is the core of a CNM system, such as the intelligent base die processing system 600, and may, for example, include one block per HBM channel. For example, the intelligent base die processing system 600 may include 16 HBM channels corresponding to 16 HBM dies. In such an example, the intelligent base die processing system 600 may include a first instance of the processor block 618 for a first HBM channel (identified by “Channel 0”) corresponding to the first HBM die 606 and a sixteenth instance of the processor block 618 for a sixteenth channel (identified by “Channel 15”) corresponding to the second HBM 608. The NOC 620 can be configured to interconnect the plurality of instances of the processor block 618. For example, the processor block 618 for the first channel can transmit data to and/or receive data from the processor block 618 for the sixteenth channel via the NOC 620. An enlarged representation of the processor block 618 of FIG. 6 is shown in FIG. 7 for enhanced clarity.

FIG. 7 illustrates an instance of the processor block 618 of FIG. 6. The processor block 618, or portion(s) thereof, may be processor circuitry. In the illustrated example, the processor block 618 includes two instances (e.g., copies) of the following components, one per pseudo channel 702, 704: a DMA-XPOSE component 706 (e.g., subsystem or module), a tightly coupled memory (TCM) 708, a processor 710, and a pseudo channel physical interface (PCn-Phy) 712, 714 where “n” is 0 or 1 for the different components. For example, the pseudo channel physical interface 712, 714 includes PC0-Phy 712 for pseudo channel 0 (PC0) and PC1-Phy 714 for pseudo channel 1 (PC1).

In some embodiments, the pseudo channel physical interfaces 712, 714 can be memory interfaces configured to drive the HBM dies 606, 608. For example, the pseudo channel physical interfaces 712, 714 can be configured to provide and/or implement a physical interface between the processor block 618 and the HBM dies 606, 608.

As shown, the processor block 618 further includes the system physical interface (S-Phy) 716, at least a portion of a crossbar 718, an HBM controller 720, and a master physical interface (M-Phy) 722. The master physical interface 722 may alternatively be referred to as a “primary physical interface.”

In some embodiments, the DMA-XPOSE component 706 is implemented by a controller. The controller can be a direct memory access (DMA) controller. Examples of the DMA controller include an application specific integrated circuit (ASIC), a field programable gate array (FPGA), a microcontroller, a programmable array logic (PAL), a programmable logic array (PLA), a programmable logic device (PLD), and other customizable and/or programmable devices. For example, the DMA-XPOSE component 706 can be a DMA controller configured to execute DMA operations to and from TCMs in any processor blocks or its associated pseudo-channel. For example, the DMA-XPOSE component 706 for Channel 0 of FIG. 6 can be configured to execute DMA operations to and from the TCM 708 for Channel 1, Channel 2, and so on.

In some embodiments, the TCM 708 can be configured to operate as a low-latency buffer for processor data, with configurable size and organization based on application needs. An example of the TCM 708 is SRAM. For example, the TCM 708 can be a fast, low-latency, on-chip SRAM located very close to the processor 710. In some embodiments, the TCM 708 can be configured to provide single-cycle, deterministic access for code and/or data. By way of example, the TCM 708 can receive and store data that is retrieved from the HBM dies 606, 608. The TCM 708 can receive and stored processed data that is processed by the processor 710. The TCM 708 can write the processed data back to the HBM dies 606, 608.

In some embodiments, the processor 710 can be configured to execute and/or otherwise effectuate computations on memory data obtained from the HBM dies 606, 608 via the PCn-Phy 712, 714. The processor 710 can be a local processor and/or otherwise implement local control logic on the base die 602. The processor 710 may be at least one hardware processor. The at least one hardware processor may be processor circuitry (e.g., hardware processor circuitry). The at least one hardware processor may implement a logic controller (e.g., a logic-based controller). Examples of the processor 710 include an ASIC, a FPGA, a microcontroller, a PAL, a PLA, a PLD, and other customizable and/or programmable devices.

In some embodiments, the system physical interface 716 is an external interface (e.g., an external physical interface) configured to communicate with an external processor or other hardware. The system physical interface 716 may more simply be referred to as a “system interface.” For example, the system physical interface 716 can be configured to communicate with the accelerator 202. In some such embodiments, the system physical interface 716 can be configured to communicate with the accelerator 202 as if the system physical interface 716 were the memory stack 604, such as one(s) of the HBM dies 606, 608. In some embodiments, the system physical interface 716 can be configured to receive memory commands from the accelerator 202. Examples of the memory commands include read commands and write commands.

In some embodiments, the various components of the processor block 618 communicate through the crossbar 718 or directly via the NOC 620 of FIG. 6. For example, the system physical interface 716 can transmit data to and/or receive data from at least one of the DMA-XPOSE component 706, the TCM 708, the processor 710, the HBM controller 720, the pseudo channel physical interface 712, 714, or the master physical interface 722 via the crossbar 718.

In some embodiments, the crossbar 718 can be implemented by one or more crossbar switches. For example, the crossbar 718 can be a data interconnect that implements a switching fabric, which enables multiple inputs to connect to multiple outputs substantially simultaneously. The switching fabric can be a grid-based interconnection network with a crossbar switch at each intersection. Examples of the crossbar switch include a memristor and a transistor. The memristor or the transistor can be configured to operate as an ON/OFF switch to complete the data transmission path.

In some embodiments, the HBM controller 720 can be configured to oversee requests from the base die 602 to the connected HBM channel and PCn-Phy blocks. The HBM controller 720 can be implemented by at least one hardware processor. For example, the processor 710 can be at least one first hardware processor and the HBM controller 720 can be at least one second hardware processor. Examples of the HBM controller 720 include an ASIC, an FPGA, a microcontroller, a PAL, a PLA, a PLD, and other customizable and/or programmable devices.

Additionally, the system physical interface 716 can be configured to receive requests originating from the accelerator 202 and route them to the master physical interface 722 and/or the pseudo channel physical interfaces 712, 714. As noted, the NOC 620 may be configured to operate as a global interconnect to facilitate data transfers between pseudo-channel DMA blocks (e.g., the DMA-XPOSE component 706) and connected TCMs (e.g., the TCM 708).

By way of example, the system physical interface 716 can be configured to receive a memory command from the accelerator 202 and output the memory command to the HBM controller 720. In such an example, the HBM controller 720 can be configured to execute and/or perform command decode, which is the process of translating high-level read/write requests (e.g., from the accelerator 202 via the system physical interface 716) into specific, timed binary commands. In some embodiments, the HBM controller 720 can translate logical memory addresses (e.g., logical block addresses) referenced by the memory commands into physical memory addresses (e.g., physical block addresses), such as physical bank, row, and column addresses used by the HBM dies 606, 608. In some embodiments, the HBM controller 720 can receive physical memory addresses referenced by the memory commands and map the physical memory addresses into physical bank, row, and column addresses used by the HBM dies 606, 608.

Returning to FIG. 6, in some embodiments, the NOC 620 includes 32 requestors and 32 targets for the 32 pseudo channels in HBM3. In other specifications, such as in HBM4 or custom configurations, there may be additional requestors, additional targets, and/or additional pseudo channels. For example, HBM4 implementations may include 64 requestors and 64 targets for the 64 channels. While implementing a full 32×32 crossbar is one option for the NOC 620, various other configurations are possible and may be advantageous. With continued reference to FIG. 6, the global signal handler 616 can be configured to process the various signals set forth in the specification for HBM3, HMB4, or another specification. For example, the global signal handler 616 may handle the signal called out in Table 2 of the JEDEC JESD238A specification.

In some embodiments, the base die 602 includes substantially all of the functionality and interface features of a non-intelligent HBM base die. For example, the base die 602 includes the system physical interface 716 to allow requests from the accelerator 202 to be directly routed to the HBM dies 606, 608 like a simple base die would operate under such conditions.

Referring to FIG. 6, when the system physical interface 716 receives memory commands that do not target the base die 602 (e.g., they target the HBM dies 606, 608), the base die 602 can establish a direct connection between the system physical interface 716 and the master physical interface 722 and the appropriate pseudo channels (e.g., PC0-Phy and/or PC1-Phy). In some embodiments, this connection process is facilitated through “digital switching,” whereby HBM signals from the system physical interface 716 are initially converted to standard CMOS logic levels, subsequently routed as needed, and then reconverted to HBM signal levels by the master physical interface 722 on a per-pseudo channel basis.

HBM3 supports up to 64 gigabytes (GB) of addressable memory in a 16-high stack of HBM memory dies. For example, the memory stack 606 can be a 16-high stack of the HBM dies 606, 608. Typically, all memory addresses within this range are routed to the HBM stack. However, in some embodiments, communication with the base die 602 is enabled by allowing a portion of the memory addresses to be excluded or “carved out” from the full 64 GB range of memory addresses. The carved-out memory addresses may, for example, include unimplemented addresses (e.g., unimplemented memory addresses) in the HBM stack. For example, if a manufacturer, a vendor, etc., uses an 8-high stack of 16 Gb devices, this will provide a total addressable and implemented range of 16 GB of memory addresses. Memory addresses beyond this range are unimplemented and can be utilized by the base die 602 to carve out addresses to effectuate local processing on the base die 602. If the complete 64 GB of memory permitted by the HBM3 standard is implemented, a carveout of memory addresses for computation commands by the base die 602 can still be implemented, but it will result in a reduction of available memory.

In some embodiments, the intelligent base die processing system 600 can be associated with a complete or total available range of memory addresses. The available range of memory addresses (e.g., the complete/total available range of memory addresses) can include a first plurality (e.g., a first subset, a first portion) of the available range of memory addresses and a second plurality (e.g., a second subset, a second portion) of the available range of memory addresses. The available range of memory addresses may be more simply referred to as “available memory addresses.” The first plurality of the available range memory of addresses can be implemented memory addresses. The second plurality of the available range of memory addresses can be non-implemented memory addresses (e.g., carved out memory addresses).

In some embodiments, the first plurality of the complete available range of memory addresses refers to the memory addresses that map to the physical HBM banks (e.g., the “implemented” memory). For example, the first plurality of the complete available range of memory addresses can refer to the memory addresses that map to the memory banks 306 of the HBM dies 216. In another example, the first plurality of the complete available range of memory addresses can refer to the memory addresses that map to memory banks of the HBM dies 606, 608.

In some embodiments, the non-implemented memory addresses are those addresses of the complete available range of memory addresses that are not needed to complete the mapping to the physical HBM banks (e.g., because there are more memory addresses available in the complete available range of memory addresses than there are actual HBM banks). A block address range (BAR) carveout refers to a reserved block of addresses within the HBM's overall address space that is allocated to the base die 602 rather than to the actual HBM dies 606, 608. This carveout subset of memory addresses may be a continuous range of memory addresses (e.g., a BAR carveout). This carveout subset can be carved out memory addresses (also referred to herein as “carveout memory addresses”). Alternatively, the carveout subset may include several discontiguous ranges of memory addresses and/or a plurality of discrete, discontiguous memory addresses. As described herein, the carveout memory addresses are set aside for use by the base die 602 to, for example, store data or instructions and enable the base die 602 to carry out near-memory compute operations. The system physical interface 716 of the base die 602 may intercept read commands or write commands (e.g., from the accelerator 202) that reference an address in a carveout region of the memory addresses and route them to the onboard processor 710 rather than passed on to the HBM dies 606, 608.

By way of example, the processor block 618 can be configured to receive, by using the system physical interface 716, a command referencing a memory address. The processor block 618 can retrieve, by using the pseudo channel physical interface 712, 714 configured to drive the HBM dies 606, 608, data from the memory stack 604 for storage in the TCM 708 accessible by the processor 710 when the memory address is associated with the plurality of carveout memory addresses. For example, the processor block 618 can be configured to determine that the memory address is one of the carveout memory addresses and the processor block 618 can be configured to retrieve the data from the memory stack 604 based on results of the determining. Furthering the example, the processor block 618 can process, by using the processor 710, the retrieved data to generate processed data, and output the processed data. In some embodiments, the processor block 618 can be configured to output the processed data by storing the processed data in the HBM dies 606, 608. For example, the processor block 618 can writing the processed data back in the HBM dies 606, 608. In some embodiments, the processor block 618 can be configured to output the processed data by transmitting, by using the system physical interface 716, the processed data to the accelerator 202 coupled to the base die 602.

In some embodiments, the processor block 618 can be configured to route processing of the command to the processor 710. For example, the processor 710 can be configured to route the command from the system physical interface 716 to the DMA-XPOSE component 706, and route, by using the pseudo channel physical interface 712, 714, the command from the DMA-XPOSE component 706 to the HBM dies 606, 608 to cause the HBM dies 606, 608 to output the data for storage in the TCM 708.

By way of another example, the processor block 618 can be configured to route, by using the pseudo channel physical interface 712, 714, the command to the HBM dies 606, 608 when the memory address is associated with the plurality of implemented memory addresses. The processor block 618 can route the command from the system physical interface 716 to the crossbar 718. The processor block 618 can route the command from the crossbar 718 to the HBM controller 720. The processor block 618 can route, by using the pseudo channel physical interface 712, 714, the command from the HBM controller 720 to the HBM dies 606, 608.

The inventors have recognized that utilizing controllers on both the accelerator 202 and the base die 602 introduces the potential issue of “dueling controllers,” where conflicting commands may be issued to one of the HBM dies 606, 608. Each controller independently maintains the status of every bank in each HBM die 606, 608 without awareness of the state of the other controller. Synchronizing state updates between the two controllers is impractical, and achieving command coordination presents significant challenges.

In some embodiments, the potential issue of “dueling controllers” is addressed by maintaining a full controller on the accelerator die 202. In some such embodiments, the system physical interface 716 and/or, more generally, the processor block 618, monitors all memory commands between the accelerator controller and HBM dies, keeping two separate status states: one for itself and one for the accelerator 202. With knowledge of the commands from the accelerator 202, the accelerated computing system 200 avoids issuing conflicting commands to the HBM dies 606, 608.

In other embodiments, only the base die 602 has a controller. In this scenario, the interface between the accelerator 202 and the base die 602 becomes “dumb,” meaning the accelerator 202 does not maintain the state of the HBM dies 606, 608, nor does the accelerator 202 attempt to schedule bank activity in the HBM dies 606, 608. Instead, these functions are performed solely by the base die 602. In some instances, this may cause the HBM communication protocol between the accelerator 202 and the base die 602 to become suboptimal due to the rudimentary row-column model of memory. Some embodiments utilize a simplified “bus-like” protocol, like the Advanced Microcontroller Bus Architecture (AMBA) provided by Arm Holdings plc of Cambridge, United Kingdom, to issue read and write commands, despite such an interface being non-standard.

The embodiments above describe a scenario in which the interfaces adhere to the HBM standard, including the interface from the accelerator die 202 to the base die 602 and the interface from the base die 602 to the memory stack 604. In some embodiments, the interface from the accelerator die 202 to the base die 602 may utilize Universal Chiplet Interconnect Express (UCIe). In some such embodiments, the accelerator 202 (or a host processor acting as controller) may similarly be “dumb” regarding HBM activity, with all scheduling and memory-state tracking offloaded to the base die 602. Alternatively, any custom or standardized high-speed interface(s) and/or associated protocol(s) may be utilized that operate at bandwidths corresponding to that of the HBM dies 606, 608.

In some embodiments, the accelerated computing system 200 of FIG. 2 includes a single controller within the base die 218 and a “dumb” controller in the accelerator 202. In some such embodiments, the accelerated computing system 200 may utilize the HBM standard protocol between the accelerator 202 and the base die 218. Conventional HBM memories lack an explicit interrupt signal. Accordingly, in some embodiments, the accelerated computing system 200 can be configured to implement a polling function where the accelerator 202 can repeatedly read a fixed address in the BAR carveout, as described above. The inventors have recognized that continuous polling is not optimal for performance or power efficiency. In other embodiments, the accelerated computing system 200 can be configured to use the reserved encoding of TEMP[1:0] encoding (“10”) as an interrupt signal. TEMP[1:0] is shown as part of the global group 312 of FIG. 3. This approach may not work with all existing HBM controllers but can work with the HBM controller 720 described herein. In some embodiments, the accelerated computing system 200 may be configured to use an interrupt output signal defined by a future HBM specification (no such interrupt currently exists). The per-channel RFU (reserved for future use) signal may not work well as an interrupt since this only works during read commands. The RFU signal is shown as part of the clock group 320 in FIG. 3.

In some embodiments, the accelerated computing system 200 implements a sideband interrupt signal (e.g., a dedicated sideband signal) outside the HBM standards. The dedicated sideband signal may be distinct and/or otherwise separate from the pseudo channel physical interface 712, 714. In some such embodiments, custom HBM controllers may be utilized to generate the sideband interrupt signal. For example, the HBM controller 720 can be a custom HBM controller configured to provide a single interrupt signal for all 16 HBM channels in the base die 602. If any processor block (e.g., from the host system 204) requires service from the accelerator 202, the processor block can raise the interrupt to that accelerator 202 to indicate to the accelerator 202 that data is ready for consumption. The interrupt can remain asserted until the accelerator 202 reads an event queue stored in the BAR carveout.

Additionally, in some embodiments, vendor-specific bits in one or more mode registers (e.g., MR10) contained in the HBM dies 606, 608 may be used in tandem with the sideband interrupt to convey interrupt causes or priority levels for one or more processor blocks of the host system 204. This enables the base die 602 to coordinate multiple simultaneous interrupt requests, preventing collisions if multiple channels raise service events simultaneously. The accelerator 202 can dynamically query these status bits stored in the HBM dies 606, 608 through the existing HBM interface, allowing for scalability with future expansions in channel count and/or processing resources.

In some embodiments, the HBM dies 606, 608 respectively contain 16 mode registers (MRs) identified by a 5-bit field “MA[4:0]”; MA[4] is reserved and must be set to zero. The mode registers are write-only and are 8 bits wide per channel, with each channel having its own separate copy of the mode registers. Alternatively, the HBM dies 606, 608 may include a different number of mode registers and/or may be a different number of bits wide per channel. Two of these registers, MR10 and MR12, are designated for vendor-specific functions, and the accelerated computing system 200 may be configured to utilize either one or both. In some embodiments, commands to MR10 in the HBM dies 606, 608 can trigger base die computation actions (e.g., processing by the processor 710), while MR12 remains unused. In some embodiments corresponding to HBM3 and earlier versions, MR10 may be defined for all 16 channels. In some embodiments corresponding to HBM4 and other versions, channels 16-31 are reserved for future applications.

The inventors have recognized within the context of this disclosure that having programmable processors creates opportunities for malicious actors (e.g., attackers, hackers) to hijack a memory device. In some embodiments, the intelligent base die processing system 600 of FIG. 6 may implement a “root of trust” feature, signed/encrypted executables, and/or secure operating modes. For example, in some embodiments, the intelligent base die processing system 600 may include and/or otherwise incorporate a hardware root-of-trust (RoT) 622 (or RoT hardware) that provides secure key storage (e.g., one-time programmable memory or electronic fuses (eFuses)). The hardware RoT 622 may alternatively or additionally provide secure cryptographic operations (e.g., signing, encryption, hashing). The hardware RoT 622 may alternatively or additionally provide secure boot and code authentication. The hardware RoT 622 may alternatively or additionally provide device identity and attestation. By way of example, the hardware RoT 622 can be embedded in the base die 602 to authenticate code and protect programmable processing logic from unauthorized access.

As shown, the hardware RoT 622 is connected to the processor block 618. For example, the hardware RoT 622 may be connected to the processor 710. Alternatively, the hardware RoT 622 may be included in and/or implemented by the processor block 618.

In embodiments in which the hardware RoT 622 is implemented, it is far harder to tamper with or bypass than it is with purely software-based solutions. The hardware RoT 622 may be, for example, the first piece of trusted code that runs at power-up/reset, verifying subsequent boot stages and any dependent security functions. In some embodiments, the hardware RoT 622 allows the software to be encrypted and signed before deployment and/or may be used to decrypt and verify code from the accelerator 202, certifying that the code is safe if it passes security checks. The base die 602 may reject unverified code and an error may be reported back to the accelerator 202.

While an example implementation of the intelligent base die processing system 600 is depicted in FIG. 6, other implementations are contemplated. For example, one or more blocks, components, functions, etc., of the intelligent base die processing system 600 may be combined or divided in any other way. The intelligent base die processing system 600 of the illustrated example may be implemented by hardware alone, or by a combination of hardware, software, and/or firmware. For example, the intelligent base die processing system 600 may be implemented by one or more analog circuits (e.g., capacitors, comparators, diodes, inductors, operational amplifiers, resistors, transistors, etc.), one or more digital circuits (e.g., logic gates, etc.), one or more hardware-implemented state machines, one or more programmable processors, one or more ASICs, etc., and/or any combination(s) thereof. The intelligent base die processing system 600 of the illustrated example can be implemented by one or more integrated circuits (ICs) on the same die or one or more ICs on two or more different dies, such as one or more ICs on a first die and one or more ICs on a second die.

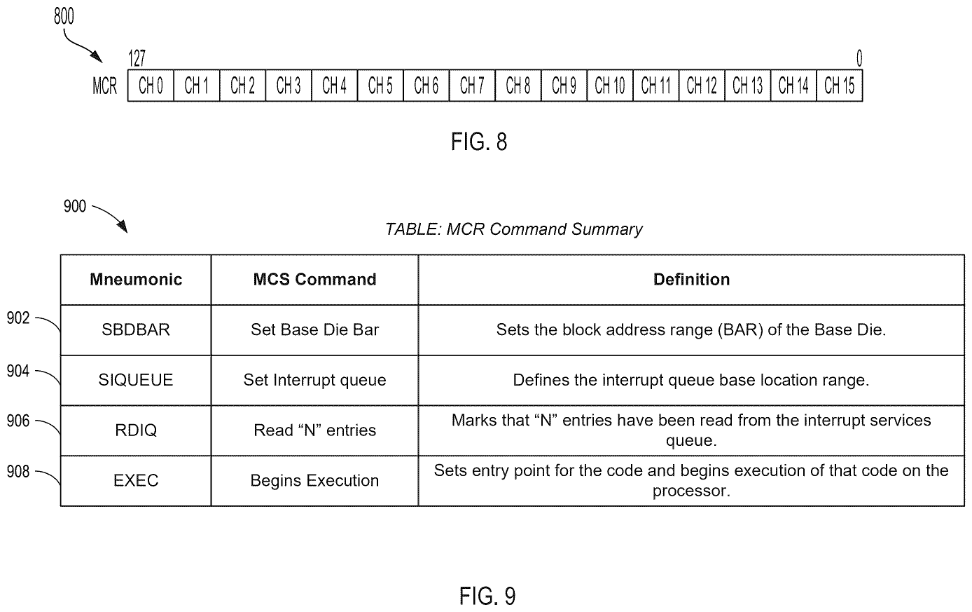

FIG. 8 illustrates an example of a master command register (MCR) 800. In some embodiments, the MCR 800 is a specialized configuration register (often a part of a set of Mode Registers (MRs)) in an HBM die that can be used to configure the operational behavior, timing, and/or functionality of the HBM die. For example, the MCR 800 can be included in and/or implemented by the memory stack 604.

The MCR 800 of this example includes a grouping of the 16 channels of MR10 values. For example, each of the HBM dies 606, 608 can include a respective register, such as a respective MR10 register. The processor block 618 can be configured to combine the respective MR10 registers into a wider control register shown as the MCR 800. Accordingly, the 16 channels of MR10 values can be combined into the MCR 800. As shown, channel 0's (CH 0) 8-bit value is the most significant bit (MSB) (identified by “127”) of the MCR 800, and channel 15's (CH 15) 8-bit value is the least significant bit (LSB) (e.g., identified by “0”), with other channels in between (e.g., CH 1, CH 2, etc.). As shown, the MCR 800 is 128 bits wide (e.g., bits 0 to 127). In other embodiments, the MR12 register could either double the MCR's bit capacity or define another register type. In other embodiments, MR10 and MR12 may be grouped differently to form more than two control registers. For example, CH0 of the MCR 800 can be in a first HBM die of the memory stack 604, CH1 of the MCR 800 can be in a second HBM die of the memory stack 604, and so on.

FIG. 9 illustrates a table 900 of four example MCR commands 902, 904, 906, 908. As illustrated, the MCR commands 902, 904, 906, 908 include a set base die BAR command 902, a set interrupt queue command 904, a read “N” entries command 906, and an execute command 908. For example, the accelerator 202 may generate and output the MCR commands 902, 904, 906, 908 to the system physical interface 716, which can be routed to the HBM controller 720 for processing.

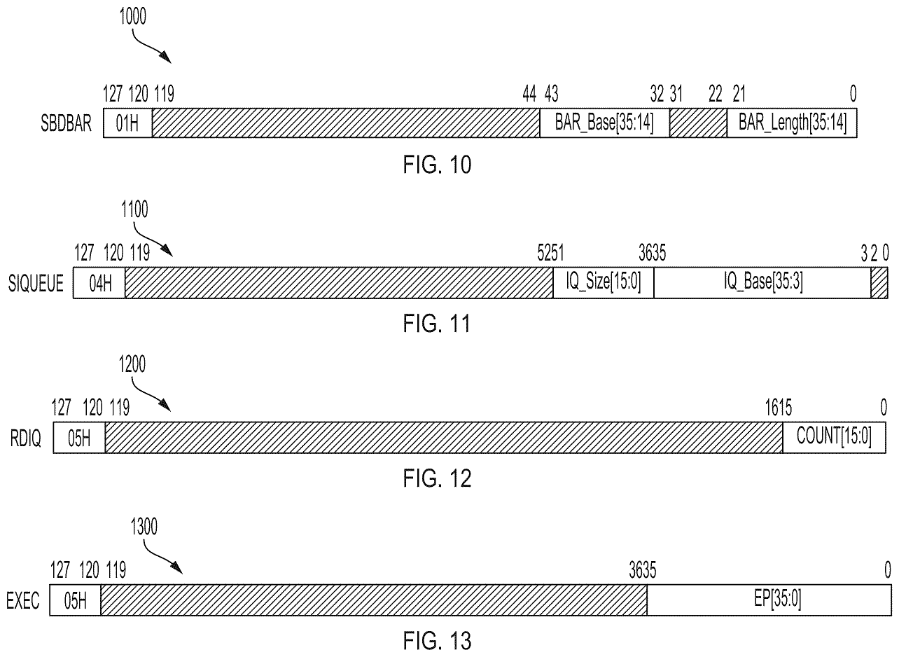

FIG. 10 illustrates an example encoding format 1000 for the SBDBAR command 902 of FIG. 9. The SBDBAR command 902 is a set base die block address range command that sets the base die block address range (BAR). The upper 8 bits encode the command as “01H” (“H” for hexadecimal), which is “00000001” in binary. “BAR_Base [35:14]” and “BAR_Length [35:14]” define the upper 22 bits of base and bounds for a single segment of addressable memory, with the low 14 bits assumed to be zero. This aligns the segment on 16 KiB page boundaries and increments its size by 16 KiB. Across 16 channels, this corresponds to 1 KiB per channel, the pseudo-channel page size in HBM3. Unused fields are shaded and must be zero (MBZ).

Once configured, all accesses on any channel to a block in the BAR segment will target base die memory, not HBM die memory. For example, a memory command received by the base die 602 that references a memory address in the BAR segment will cause the base die 602 to perform local processing on data retrieved from the HBM dies 606, 608. In such an example, the base die 602 suppresses these read/write requests, preventing them from reaching the HBM dies 606, 608. This applies to all activate, read, read with AP, write, and write with AP commands, as interpreted by the last activate command per bank. The illustrated example includes only one BAR, but more BARs could be defined for enhanced software control. In another example, a memory command received by the base die 602 that does not reference a memory address in the BAR segment will cause the base die 602 to retrieve data from the HBM dies 606, 608 and output the retrieved data to the data requestor, such as the accelerator 202.

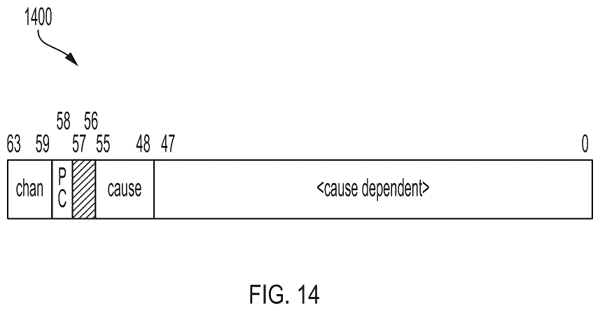

FIG. 11 illustrates an example encoding format 1100 for the SIQUEUE command 904 of FIG. 9. The SIQUEUE command is used to manage the IQUEUE discussed in connection with FIG. 14. The fields include bits IQ_Base [35:3] that set the base address to a 64-bit aligned word boundary. The accelerated computing system 200 may require that the address fall within the range of BAR_Base to BAR_Base+BAR_Length−8, as specified by the SBAR command. Bits IQ_Size [15:0] specifies the length of the IQUEUE in terms of 64-bit word entries. The accelerated computing system 200 may require that it must contain at least one entry and cannot exceed 216 entries (if IQ_Size [15:0] is set to zero). The SIQUEUE command empties the IQUEUE and removes any pending interrupt entries.

FIG. 12 illustrates an example encoding format 1200 for the read “N” entries or RDIQ command 906 of FIG. 9. The RDIQ command tells the base die 602 to discard a specified number of read IQUEUE entries. The COUNT[15:0] field indicates the number of entries read by the accelerator to be discarded, with 0 meaning to discard the entire IQUEUE. Entries are discarded from the head, and the head pointer and counter are adjusted. The interrupt signal stays asserted until all entries are read.

FIG. 13 illustrates an example encoding format 1300 for the execute or EXEC command 908 of FIG. 9. A wide variety of processors may be used in conjunction with this disclosure. Many suitable programmable processors have a code entry point, which is the memory location where code execution starts. In some embodiments, the EXEC command may be used to set this entry point for the code. The EXEC command may additionally or alternatively be used to begin the execution of that code on the processor.

FIG. 14 illustrates an example implementation of a set interrupt queue entry 1400. The interrupt queue (IQUEUE) command logs interrupt requests for transmission to the accelerator die 202. Each interrupt includes details about its source, cause, and any additional information required based on the type of interrupt. Interrupt entries are added to the interrupt queue as described herein. In some embodiments, and as illustrated, each entry may be 64 bits long. As illustrated, the source is indicated by a specific channel (5 bits) and a pseudo channel (1 bit). As shown, the interrupt cause is represented by 8 bits, although this can be adjusted in length for a particular application. The remaining 48 bits are dependent on the cause.

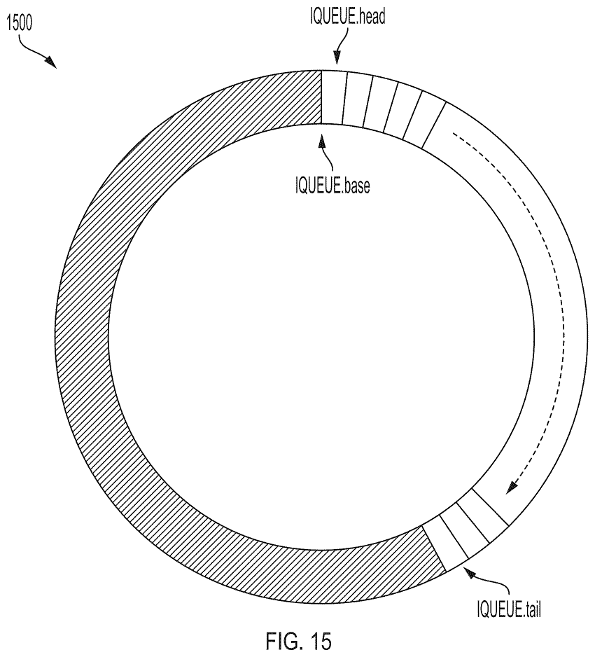

FIG. 15 illustrates an example of a circular first-in, first-out (FIFO) interrupt queue 1500. The circular FIFO interrupt queue 1500 is a FIFO buffer that can be configured to store interrupt status entries. Entries are added at the tail, increasing the tail pointer by wrapping it around and adjusting the queue counter. Entries are removed from the head with a wrap-around, decreasing the queue counter by the number of entries read.

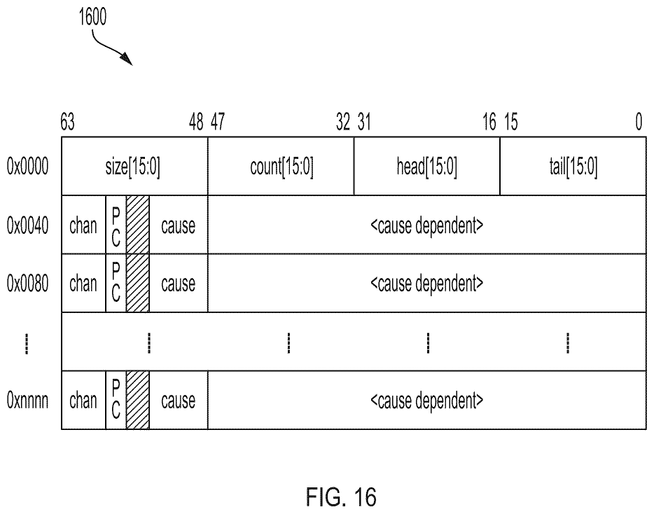

FIG. 16 illustrates an example memory layout 1600 of the IQUEUE. As shown, the first 64 bits form a control word. Specifically, the bits size [15:0] indicate the size in words of the IQUEUE, including this 64-bit word. A value of 0 is interpreted as 216 words. The bits count [15:0] indicates the number of valid entries in the IQUEUE. Since the maximum number of entries is 216 words, and this includes this word, the maximum number of entries in a queue is 0xFFFF. The bits head [15:0] provide an index of the head element. The bits tail [15:0] provide an index of the tail element. The entries in the IQUEUE are read-only, and unused entries outside of the head and tail are ignored.

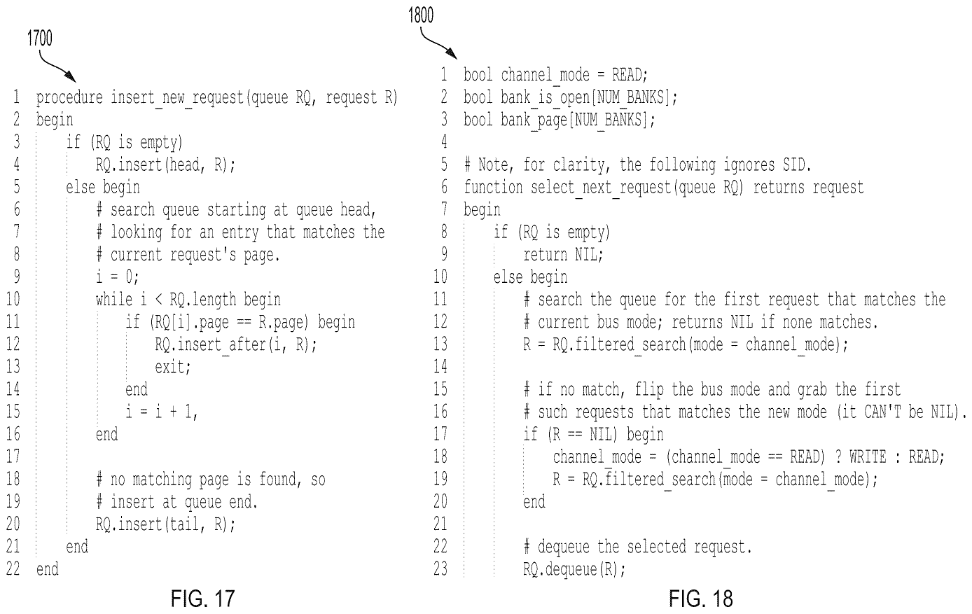

FIG. 17 illustrates pseudocode 1700 of an algorithm for inserting requests into a request queue for memory reads and writes. In some embodiments, this algorithm may be implemented by using a state machine in hardware. In some embodiments, this algorithm may be implemented by machine readable instructions that, when executed by the global signal handler 616, execute the algorithm. Alternatively, the algorithm may be implemented by the processor block 618.

Each pseudo channel in HBM3 has its own request queue, which is implemented in the processor blocks of the HBM controller, such as the HBM controller 720 of FIG. 7. This page streams sorted queue insert requests with a preference for matching 1 KiB pages in a bank, reducing page open and close commands to improve performance. Reads are prioritized over writes, and writes are grouped together to minimize bus turnarounds between the HBM dies 606, 608 and the base die 602. For example, the global signal handler 616 can be configured to perform page stream sorting to manage open memory pages in the HBM dies 606, 608. In such an example, the global signal handler 616, the processor block 618, and/or, more generally, the base die 602, can execute machine-readable instructions that implement the pseudocode 1700 to perform page stream sorting to manage open memory pages in the HBM dies 606, 608.

In some embodiments, if a bank at the head of the queue is “busy,” the global signal handler 616 may skip that bank by searching deeper into the queue, possibly masking out busy banks, or by referencing a per-bank queue. In some embodiments, the global signal handler 616 may search for activating and/or making other idle banks busy, including searching the queue beyond the head by masking busy banks and/or implementing per-bank queues. In some embodiments, the global signal handler 616 may set auto recharge if a column command will render the bank “not busy.” These approaches can be used to identify idle banks that can be activated sooner, thereby improving overall throughput.

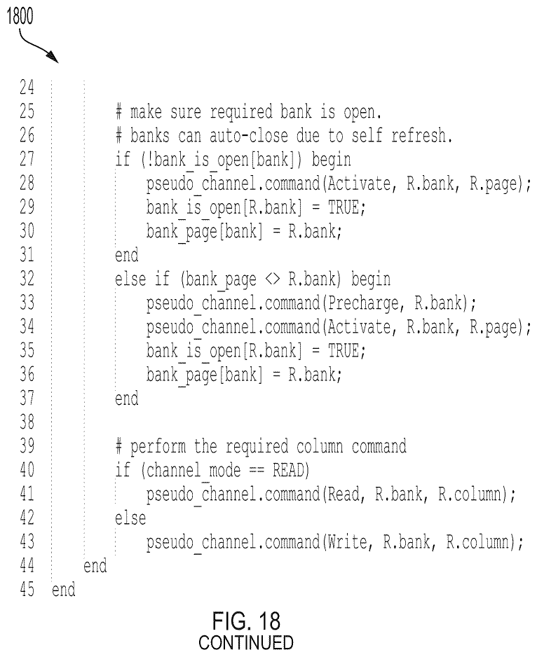

FIG. 18 illustrates pseudocode 1800 of an algorithm for pseudo-channel request queue servicing. In some embodiments, this algorithm may be implemented by using a state machine in hardware. In some embodiments, this algorithm may be implemented by machine readable instructions that, when executed by the global signal handler 616, execute the algorithm. Alternatively, the algorithm may be implemented by the processor block 618.

In some embodiments, using a custom content-addressable memory (CAM) for the nearest search or a serialized binary search can minimize the time to insert a new request into the page stream sorter. While the specific insertion search routine is not defined here, any fast algorithm can be used in the context of the present disclosure. Requests in the request queue are processed sequentially, from the first to the last, with filtered selection corresponding to the current read or write mode of the pseudo channel bus, as shown in FIGS. 17 and 18. The algorithms exemplified in FIGS. 17 and 18 do not consider HBMs' SID (stack ID) or any data sources for read and write requests. In this instance, data is sourced into and out of the associated pseudo channel's TCM.

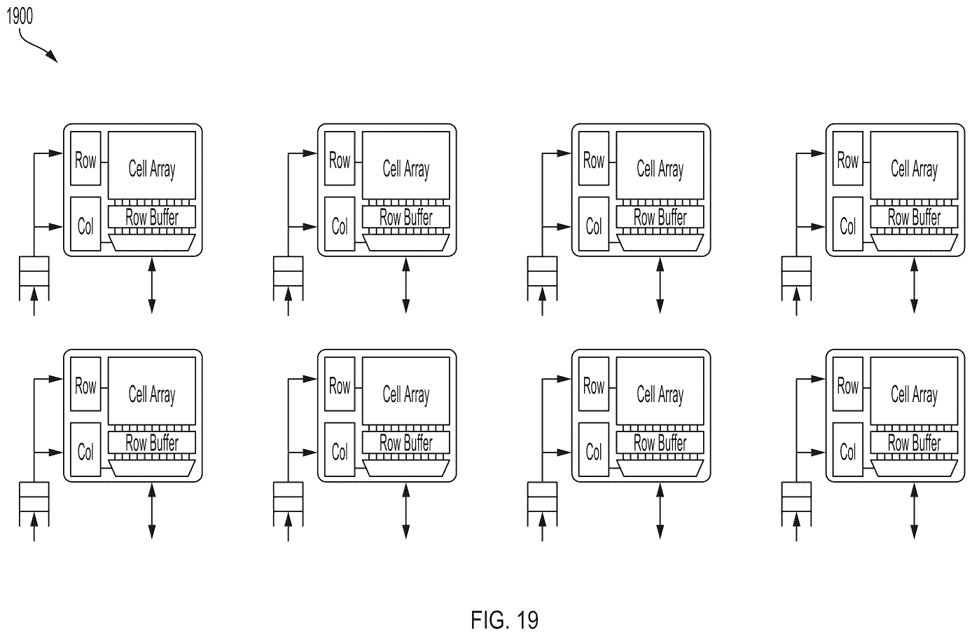

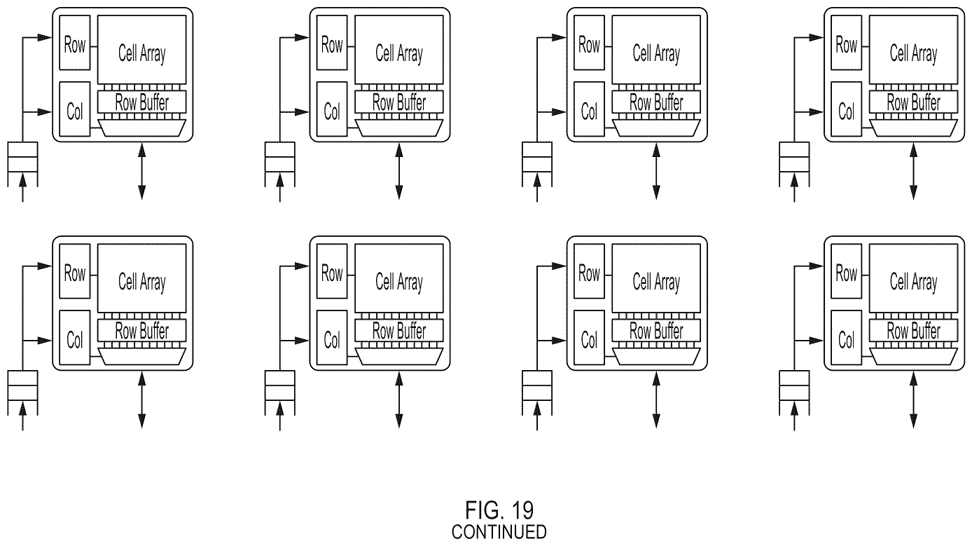

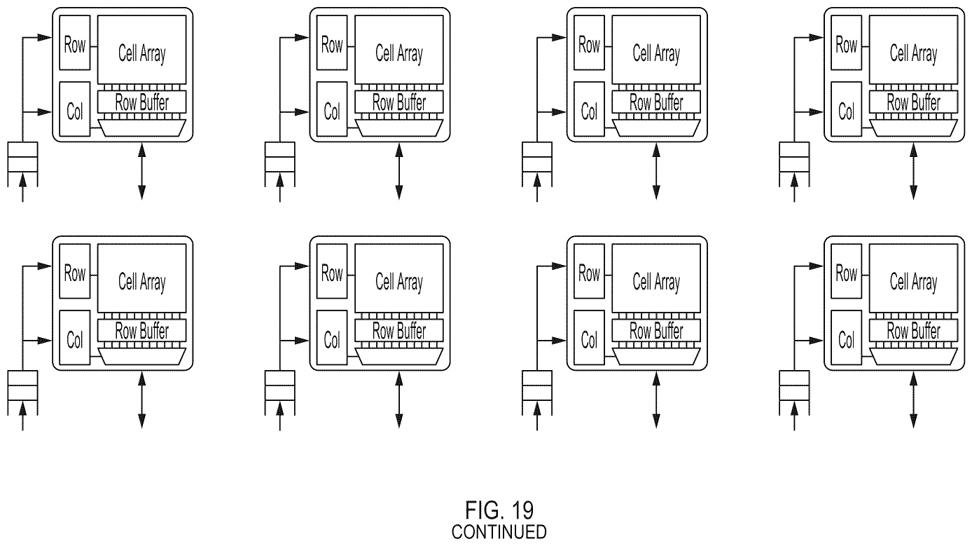

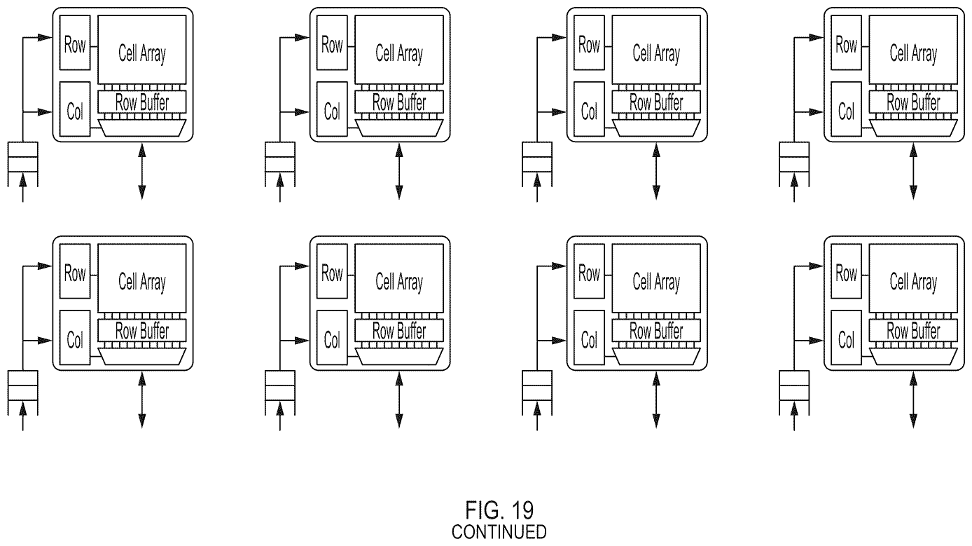

FIG. 19 illustrates an example bank configuration 1900 within an HBM pseudo channel. In some embodiments, the bank configuration 1900 is a maximal bank configuration within an HBM pseudo channel. The previously described page stream sorting selection algorithm may be suboptimal due to its sequential search of the request queue. Accordingly, in the illustrated example, 32 virtual request queues are represented as entries in a single request queue (e.g., “RQ” in the algorithms of FIGS. 17-18). The global signal handler 616 and/or, more generally, the base die 602, can implement page stream sorting within these virtual queues so that requests to idle banks can proceed even if there are pending requests to busy banks. Essentially, the global signal handler 616 and/or, more generally, the base die 602, ensures that the 32 virtual queues function independently within a common queue.

In some embodiments, a per TCM service queue, like pseudo channel request queuing, operates strictly as first-in, first-out (FIFO) without page stream sorting. The processor block 618 can be configured to handle TCM-to-TCM data transfers, allowing a pseudo channel's DMA-XPOSE component 706 to enqueue requests in a remote TCM request queue.

As described in connection with FIG. 7, per pseudo channel, the DMA-XPOSE component 706 transfers data between the HBM dies 606, 608 and the processor 710 and/or facilitates processor-component-to-processor-component transfers. The TCM 708 may be, for example, a software-controlled memory connected to both the DMA-XPOSE component 706 and its processor 710, which handles most computations in the intelligent base die 602. The processor 710 may be configured for bulk data flow operations. For example, in machine learning (ML) inference engines, neural networks are represented by directed acyclic graphs (DAGs) with interconnected nodes performing operations.

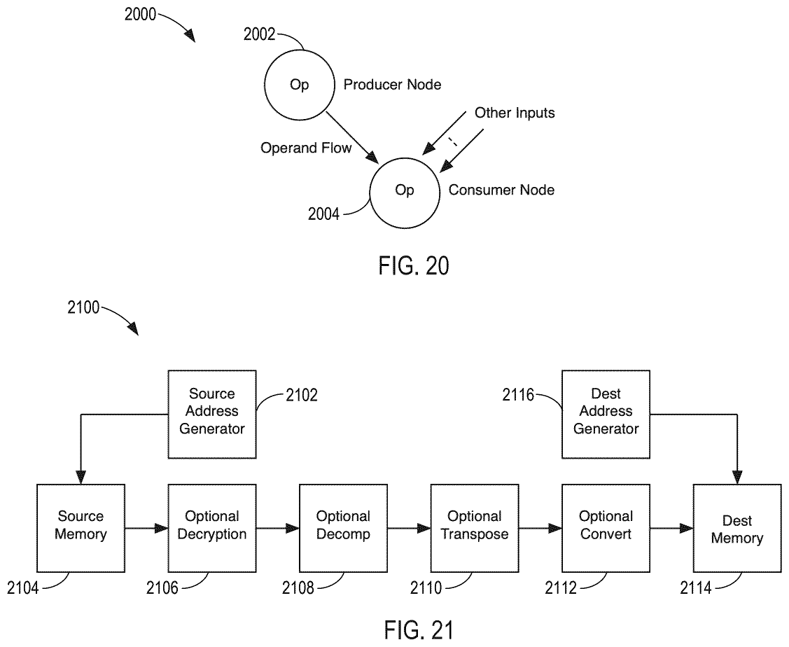

FIG. 20 illustrates an example data flow 2000 from a producer node 2002 to a consumer node 2004. Each node 2002, 2004 can be configured to use fixed-function logic (e.g., fixed-function processors) or programmable processors, and arcs can represent data flowing from producer to consumer nodes. Node functions can range from the very simple (e.g., “add two vectors”) to the very complex (e.g., “multiply two very large matrices”). Regardless, the data flow principle, according to various embodiments, is that the consumer node 2004 may not begin operation until all inputs are completely available.

FIG. 21 illustrates a flow diagram of a data transform expansion 2100. In some ML inference engines, data must be transformed before it can be operated upon. The flow diagram shown in FIG. 21 includes a source address generator 2102 configured to produce memory addresses for sourcing data, creating a sequence of memory block transfers queued at the source's memory target. A source memory 2104 contains the source data. An optional decryption block 2106 of the flow diagram represents the optional decryption of data into plain text if it is encrypted. An optional decompression block 2108 represents the decompression of the data if it is stored in a compressed format. An optional transpose block 2110 represents the reshaping of data as needed by the consumer node, such as the consumer node 2004 of FIG. 20. An optional convert block 2112 operates to convert data into the correct format as required by the consumer node. For example, conversion may include a sign extension of an 8-bit signed integer to a 16-bit signed integer. A destination address generator block 2116 generates a sequence of memory addresses pointing to where the data is to be stored. A destination memory block 2114 stores the data. The functions shown in FIG. 21 may be implemented by the DMA-XPOSE component 706 described in connection with FIGS. 6 and/or 7.

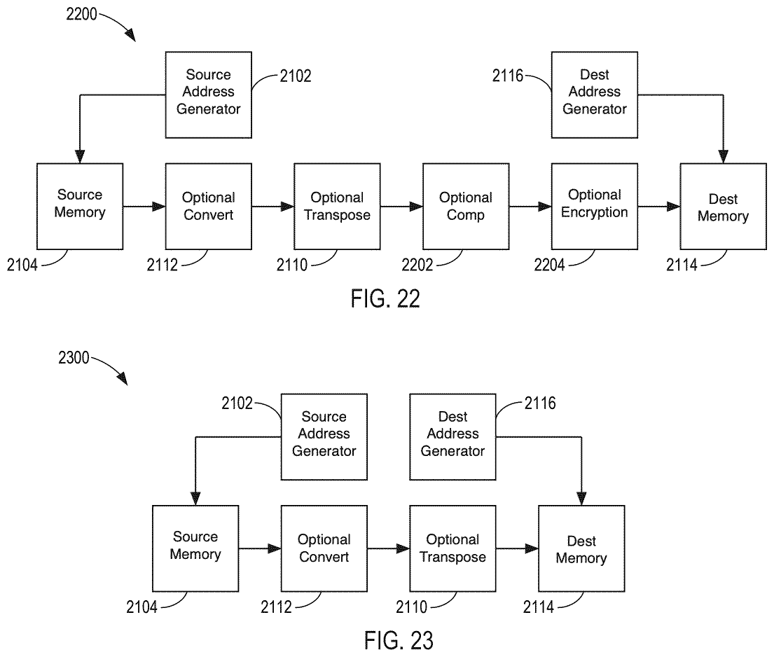

FIG. 22 illustrates a flow diagram of a data transform contraction 2200. Some of the blocks shown in FIG. 22 are the same as described in FIG. 21 but operate in reverse. Additionally, an optional compression block 2210 may operate to compress a block of data. An optional encryption block 2212 may operate to encrypt data before storing it in destination memory 2214.

The flow diagram shown in FIG. 22 includes the source address generator 2102 of FIG. 21 configured to produce memory addresses for sourcing data, creating a sequence of memory block transfers queued at the source's memory target. The source memory 2104 contains the source data. The optional convert block 2112 operates to convert the source data into the correct format as required by the consumer node, such as the consumer node 2004 of FIG. 20. For example, conversion may include a sign extension of an 8-bit signed integer to a 16-bit signed integer. The optional transpose block 2110 represents the reshaping of data as needed by the consumer node. An optional compression block 2202 represents the compression of the data if it is stored in a decompressed format. An optional encryption block 2204 of the flow diagram represents the optional encryption of data if the data is decrypted (e.g., in plain text). The destination address generator block 2116 generates a sequence of memory addresses pointing to where the encrypted data is to be stored. The destination memory block 2114 stores the encrypted data. The functions shown in FIG. 22 may be implemented by the DMA-XPOSE component 706 described in connection with FIGS. 6 and/or 7.

FIG. 23 illustrates a flow diagram of an example cache-cache transform 2300. The cache-cache transform 2300 may be a truncated transform flow based on the data transform contraction 2200 of FIG. 22. In some embodiments, the data transform expansion flow 2100 is utilized for transferring data from the HBM dies 606, 608 to level 1 (L1) cache of the processor 710. In some embodiments, the data transform contraction flow 2200 may be used to write data back to the HBM dies 606, 608 from the L1 cache (e.g., L1 cache memory) of the processor 710. When L1-cache-to-L1-cache transfers are necessary, the truncated transform flow shown in FIG. 23 is employed. The functions shown in FIG. 23 may be implemented by the DMA-XPOSE component 706 described in connection with FIGS. 6 and/or 7.

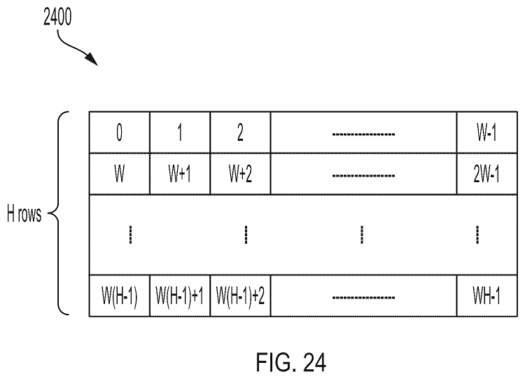

FIG. 24 illustrates an example of a pitch layout 2400 for a two-dimensional (2D) tensor. The pitch layout 2400 shown is a width-height (WH) pitch memory layout for a 2D tensor. ML inference engines use common memory layouts for tensor data storage, typically handling one-dimensional (1D), 2D, or 3D tensors. One possible layout is a serialized multi-dimensional tensor. For 2D tensors, notation includes HW or WH (height and width), while 3D tensors use CHW, CWH, WHC, or HWC, where C represents the channel or depth.

The illustrated layout is referred to as “pitch linear” in graphics and arranges data in rows of W items and H rows deep. The numbers indicate memory offsets from the layout's base. More complex layouts may pad sides to align rows to a power of 2, simplifying memory addressing. In addition to the WH order presented, alternative layouts are also feasible. Extensions to 3D or higher dimensions can be implemented. During layout-to-layout transfers, the DMA-XPOSE component 706 may interchange the order of dimensions. For instance, the DMA-XPOSE component 706 may read from a WH layout and write to an HW layout.

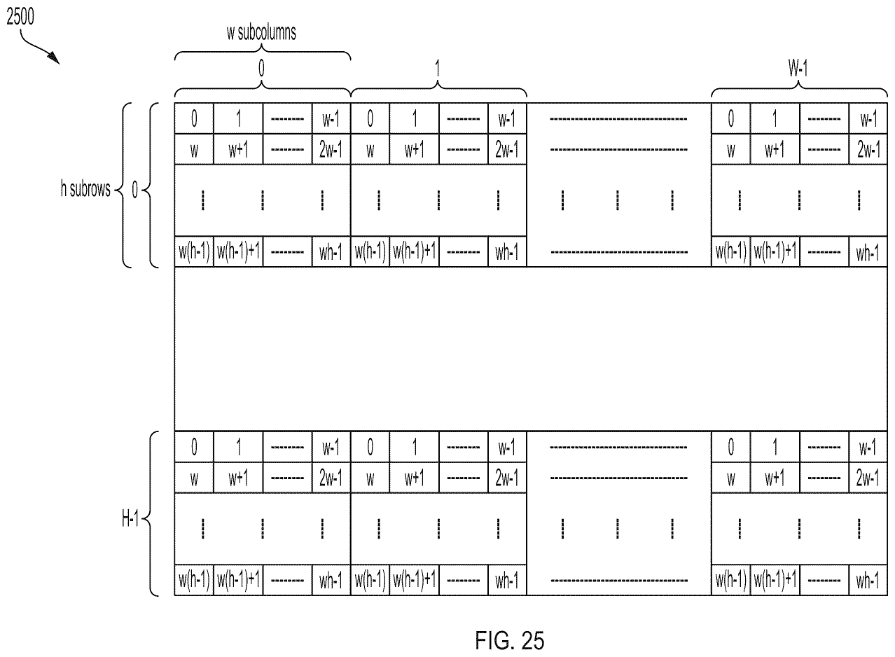

FIG. 25 illustrates an example of a block linear layout 2500. The block linear layout 2500 shown is a block linear WH layout. Block linear formats may be utilized to enhance the efficiency of certain arithmetic operations. The illustrated example is a “hyper block” layout. Inner blocks are arranged linearly with dimensions' w′ and ‘h.’ The blocks are then organized linearly with dimensions ‘W’ and ‘H.’

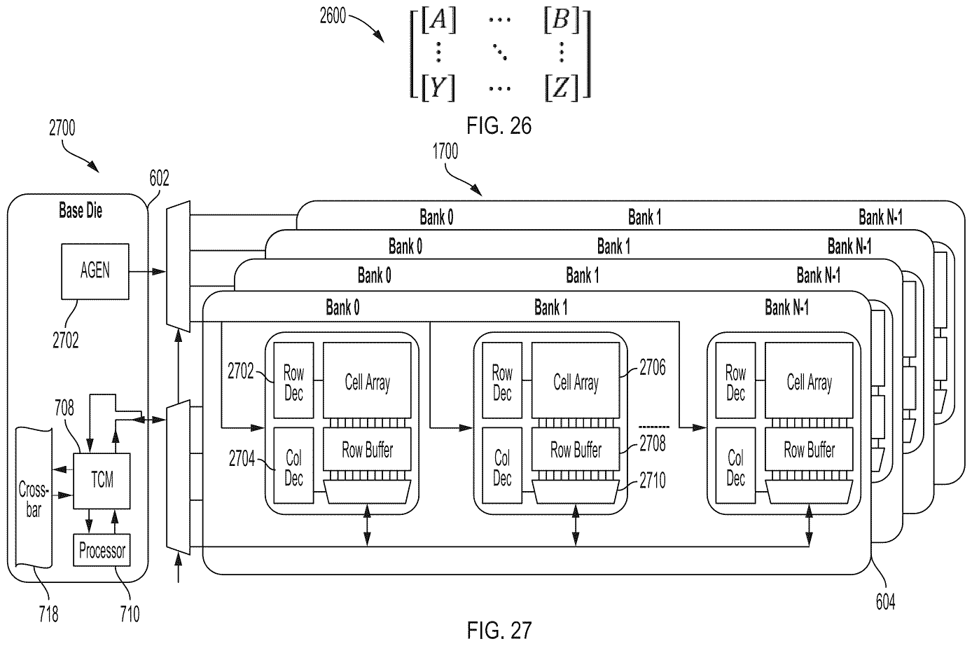

FIG. 26 is an example of a tiled matrix layout 2600. The block linear WH layout of FIG. 25 is efficient for processing matrices in tiles, such as the tiled matrix layout 2600 of FIG. 26. Matrices A, B, Y, and Z of the tiled matrix layout 2600 are themselves matrices within the outer matrix, forming tiles. These smaller matrices are generally more manageable and can be used more effectively in matrix operations due to their smaller size. The size of the tiles determines the block size employed in a block linear layout.

One approach to emulate node operations in a processor, such as the processor 710, is referred to as a fixed-function approach. The fixed-function approach includes a predefined set of operators and data structures. Another approach to emulate node operations in a processor, such as the processor 710, is referred to as a programmable approach. The programmable approach uses processors to run a program provided by the client accelerator.

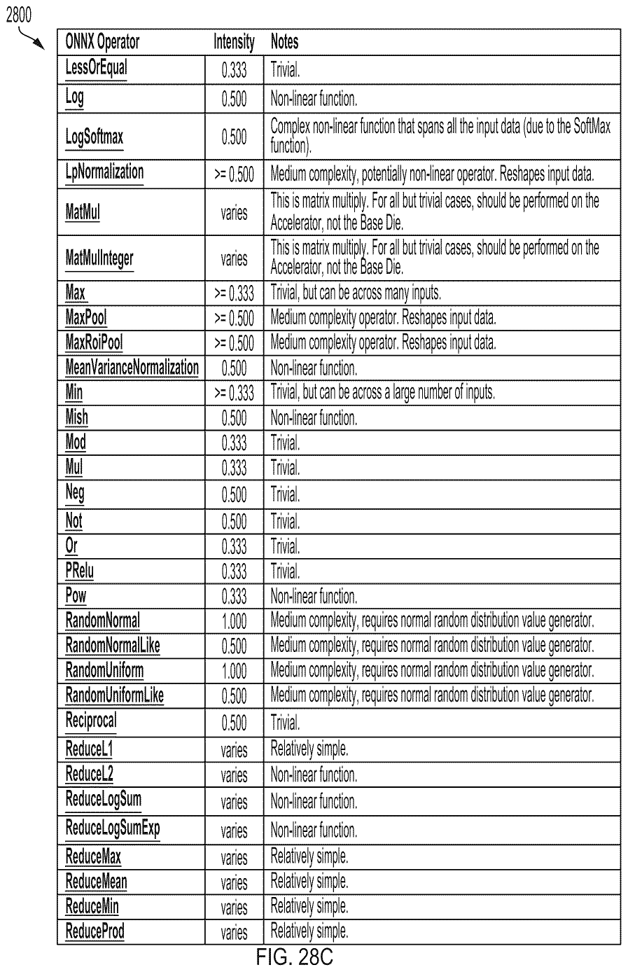

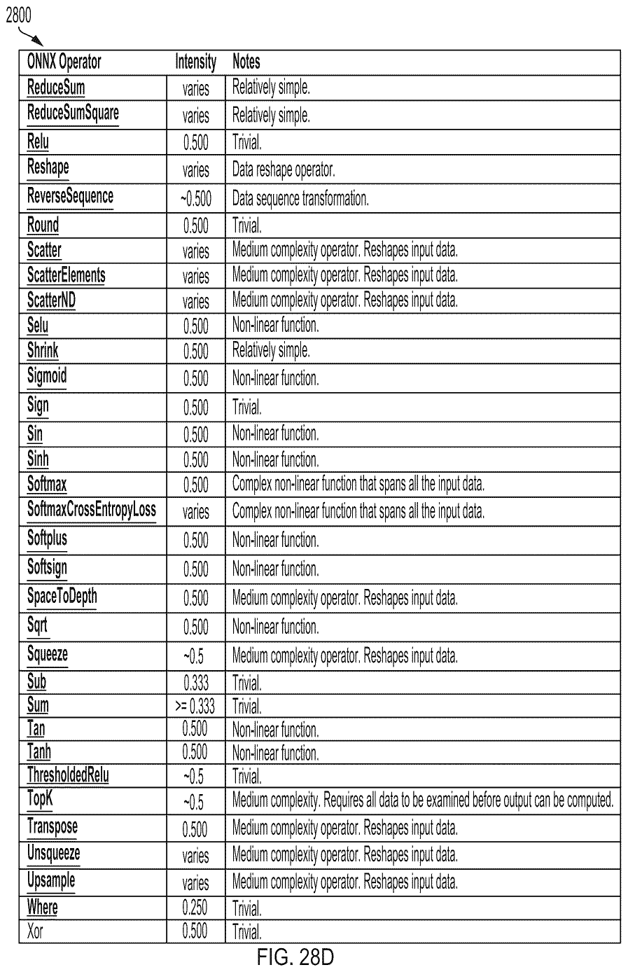

The inventors have recognized within the context of this disclosure that fixed-function blocks offer several advantages. First, they typically consume significantly less power when performing the same function compared to their programmable counterparts. Dedicated hardware can be specifically designed to match data structures with minimal overhead, resulting in superior performance as the function is predetermined during the design phase. Second, from a security standpoint, it is considerably more challenging to compromise a fixed-function machine. Some examples of fixed-function operations that could be implemented by the systems described herein include the Open Neural Network Exchange (ONNX) operators provided by the Linux Foundation® and shown in FIGS. 28A-D.

FIGS. 28A-D include a table 2800 of ONNX operators that may be implemented. For example, the processor 710 may execute code that implement at least some of the ONNX operators to execute at least one artificial intelligence and/or machine learning model. Programmable processors can emulate any type of node operation with any data structure, limited only by memory capacity. The inventors have recognized within the context of this disclosure that programmable hardware is often chosen over fixed-function hardware when the tasks to be emulated are either unknown or frequently changing. In this context, characteristics of a programmable processor include performance, efficiency, and architectural options. High-performance programmable processors fully utilize memory bandwidth from the HBM stack. High-efficiency programable processors focus on both performance per area (affecting device cost) and performance per watt (impacting energy efficiency). Architectural options for programmable processors include but are not limited to, vector processors and SIMT multithreaded processors. However, other types of programmable processors may be used instead (or additionally).

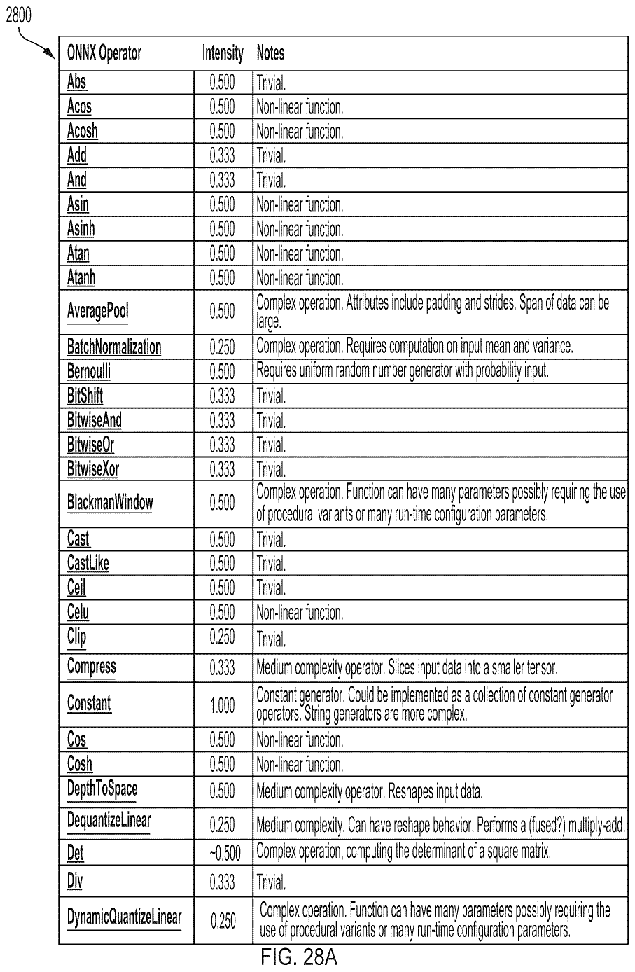

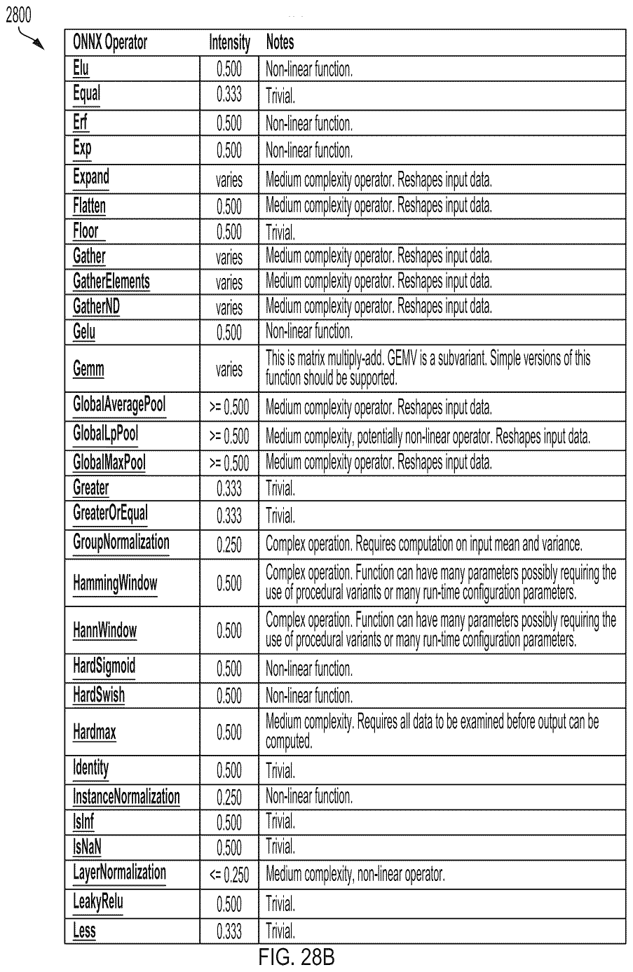

Returning to FIG. 27, a simplified performance model 2700 of each HBM pseudo channel is shown. As illustrated, a model of a portion of the base die 602 is shown on the left. The base die 602 includes an address generator (AGEN) 2702. The address generator 2702 can be configured to generate row and column addresses for the memory banks of the memory stack 604. The address generator 2702 can also be configured to generate SID (stack ID) selects if multiple HBM dies 606, 608 share a single pseudo channel.

The base die 602 includes the TCM 708, the processor 710, and the crossbar 718 of FIG. 7. The TCM 708 can be configured to buffer data to and from the memory banks. The TCM 708 may also buffer data from other TCM/processor blocks on the base die 602. The processor 710 can be programmable or fixed-function. The base die 602 can include the crossbar 718 to interconnect other processors 710 through their TCMs 708. To the right of the base die 602 are the memory banks of the HBM dies 606, 608 for that pseudo channel. Each bank has a row decoder 2702 (identified by “Row Dec”) and a column decoder 2704 (identified by “Col Dec”), an array of bit cells 2706, a row buffer 2708 (page), and a multiplexer/demultiplexer (mux/demux) 2710 to send/receive data from the base die 602. In some embodiments, the memory stack 604 shown in FIG. 27 may be implemented using the bank configuration 1900 of FIG. 19.

By way of example, the processor 710 can be configured to fetch data from the TCM 708 (the data may be originally fetched from the HBM), perform computations on the fetched data, and store the results back in the TCM 708 as processed data upon completion. In some embodiments, the processed data is stored back in the HBM dies 606, 608 of the memory stack 604. In some embodiments, the processed data is transmitted to another processor 710 via the crossbar 718. In some embodiments, the processed data is transmitted to the accelerator 202 via the crossbar 718.

In some embodiments, any pseudo channel can only be accessed for reading or writing at one time. For example, the data wires for the pseudo channel may be shared for both read and write operations and thus utilize a “bus turnaround” to transition between these states. Per HBM ½ clock cycle, only 4 bytes of bandwidth are available per pseudo channel, excluding turnaround losses. Consequently, if a processor operation requires Y bytes of bandwidth in total for its input and output (to be stored in a bank), a maximum of 4/Y operations per clock cycle can be completed by the processor. This limitation applies regardless of whether the crossbar is employed to facilitate communication between processor blocks.

Arithmetic intensity is a metric used in computer architecture, calculated as the ratio of mathematical operations to memory traffic as follows:

$$I = \frac{{N}_{m a t h}}{{N}_{memory}} , \qquad Equation ( 1 )$$

The arithmetic intensity I is the ratio of mathematical operations Nₘₐₜₕ to the amount of memory traffic N_{memory}. This traffic is measured in bytes, operands, or another consistent metric. If N_{memory} is measured in bytes, we can combine the equations to get:

$$P \leq 4 \times I , \qquad Equation ( 2 )$$

P is performance measured in operations per clock. When multiplying an M row by N column matrix by an N-element vector:

$${N}_{m a t h} = M \times N \qquad Equations ( 3 - 4 )$$

$${N}_{m e m o r y} = ( N \times M + 2 N ) \times {S}_{o p e r a n d} ,$$

Nₘₐₜₕ is measured in MAC (multiply-accumulate) operations and S_{operand} is the operand size in bytes. Thus, for large M with I measured in operations per byte, asymptomatically,

$$I = \frac{M \times N}{( N \times M + 2 N ) \times {S}_{o p e r a n d}} = \frac{M}{( M + 2 ) \times {S}_{o p e r a n d}} ≅ \frac{1}{{S}_{o p e r a n d}} , \qquad Equation ( 5 )$$

$$Or :$$

$$P \leq \frac{4}{{S}_{o p e r a n d}} , \qquad Equation ( 6 )$$

Beneficially, the architecture may be configured to maintain simplicity and compactness in the base die architecture. For example, the processor 710 may be configured to handle operations with low arithmetic intensity and exhibit relatively modest performance compared to its memory bandwidth. This approach strategically channels high-intensity operations to the primary accelerator die 202, aligning with expected outcomes.

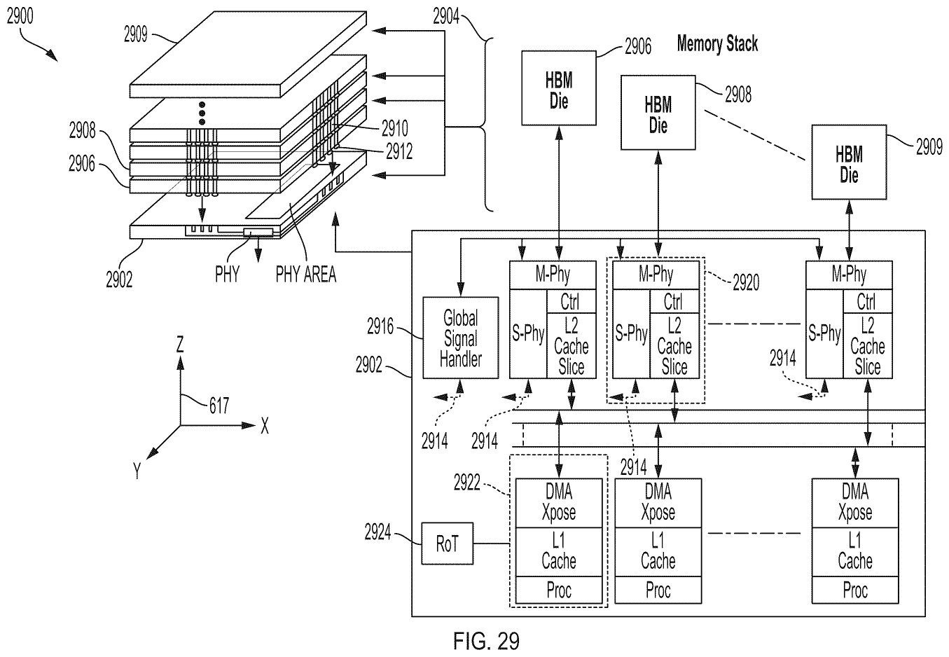

FIG. 29 illustrates a block diagram of another example implementation of an intelligent base die processing system 2900 for HBM memory. As illustrated, the architecture may include a number of HBM dies 2906, 2908, 2909 in a memory stack 2904. The number of HBM dies 2906, 2908, 2909 can be a number in a range of 4-16 HBM dies. These HBM dies 2906, 2908, 2909 may, as previously described, connect to a single base die 2902 at the bottom of the memory stack 2904 using TSVs 2910. The TSVs 2910 may connect together microbumps 2912 as shown inset in FIG. 29. Signals 2914 represent HBM connections to an external processor, host, or accelerator (not shown). The external signals 2914 may, for example, conform to JEDEC standards for HBM signaling, as previously described herein. For example, global signal handler 2916 and the signal 2914 may correspond to the temperature and test logic 314 and the global group 312, respectively, such that the global signal handler 2916 may receive the signals 2914 from the accelerator 202 of FIGS. 2 and/or 3.

The base die 2902 of FIG. 29 includes instances of a channel block 2920 and a processor block 2922. The channel block 2920 may be channel block circuitry. The processor block 2922 may be processor circuitry.

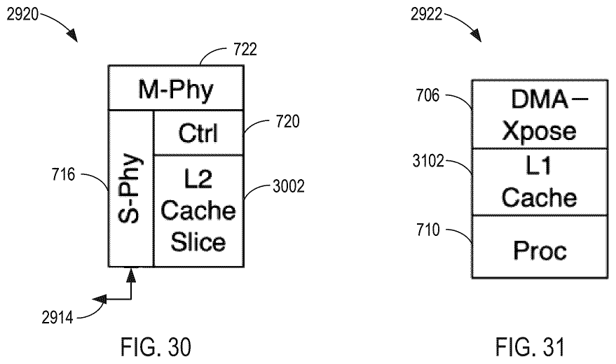

FIG. 30 illustrates an example channel block architecture. In some embodiments, the channel block architecture implements the channel block 2920 of FIG. 29. For example, the channel blocks 2920 can directly control each HBM die channel. As shown, the channel blocks 2920 may respectively include the system physical interface 716 (identified by “S-Phy”) of FIG. 7, the HBM controller 720 (identified by “Ctrl”) of FIG. 7, the master physical interface 722 (identified by “M-Phy”) of FIG. 7, and a level 2 (L2) cache slice 3002 (identified by “L2 Cache Slice”). The L2 cache slice 3002 can be a slice of a larger cache memory. For example, the L2 cache slice 3002 can be a portion (e.g., a slice) of an L2 cache memory (e.g., an L2 interleaved cache memory).

The master physical interface 722 can be configured as a memory physical interface (also referred to as a “master physical interface”) that directly controls the HBM die to which it is attached. The system physical interface 716 can be configured as a slave physical interface that communicates with the accelerator 202 and emulates the interface so that the accelerator 202 can see if it is directly connected to the HBM die 2906, 2908, 2909 instead of the base die 2902. The HBM controller 720 can be a controller for the master physical interface 722 that handles base die-sourced memory transactions. The HBM controller 720 can also be configured to service custom process requests from the accelerator 202 sourced by the system physical interface 716 and operates as a bridge between the system physical interface 716, the master physical interface 722, and the internal processing logic shown as the processor 710 in FIG. 31. The L2 cache slice 3002 can be configured to cache memory transactions sourced from the system physical interface 716 to the processor 710 or memory transactions sourced by those processors 710 destined for the master physical interface 722 or as a response to the system physical interface 716.

FIG. 31 illustrates an example processor block architecture. In some embodiments, the processor block architecture implements the processor block 2922 of FIG. 29. As shown, the processor blocks 2922 may respectively include the DMA-XPOSE component 706 of FIG. 7, the processor 710 of FIG. 7, and a level 1 (L1) cache 3102.

As illustrated, the DMA-XPOSE component 706 can be configured to handle DMA, transpose, and recode operations. The DMA-XPOSE component 706 can be configured to transfer blocks between memory (with L2 as a proxy) and other L1 cache blocks. The DMA-XPOSE component 706 can be configured to layout and/or format conversion in the transfer. The L1 cache 3102 is a level 1 software-managed cache, which services as tightly coupled memory to the processing block. For example, the L1 cache 3102 can implement and/or correspond to the TCM 708 of FIG. 7. In some embodiments, the processor 710 can be either a fixed function, meaning it can execute from a fixed palette of operations, or be programmable (e.g., vector or multithreaded).

As previously described, the device switching within the channel block 2920 may be accomplished through digital switching utilizing logic gates. In other embodiments, the device switching within the channel block 2920 may be accomplished through analog switching, where signals are routed via wires and analog amplifiers. A benefit for employing analog switching would be to minimize latency (e.g., pass-through latency), particularly in the base die “pass through” function where the accelerator 202 aims to directly control the memory stack 2904.

The inventors have recognized within the context of this disclosure that having programmable processors creates opportunities for malicious actors (e.g., attackers, hackers) to hijack a memory device. In some embodiments, the intelligent base die processing system 2900 of FIG. 29 may implement a “root of trust” feature, signed/encrypted executables, and/or secure operating modes. For example, in some embodiments, the intelligent base die processing system 2900 may include and/or otherwise incorporate a hardware RoT 2924 that provides secure key storage (e.g., one-time programmable memory or electronic fuses (eFuses)). The hardware RoT 2924 may alternatively or additionally provide secure cryptographic operations (e.g., signing, encryption, hashing). The hardware RoT 2924 may alternatively or additionally provide secure boot and code authentication. The hardware RoT 2924 may alternatively or additionally provide device identity and attestation. As shown, the hardware RoT 2924 is connected to the processor block 2922. For example, the hardware RoT 2924 may be connected to the processor 710. Alternatively, the hardware RoT 2924 may be included in and/or implemented by the processor block 2922.

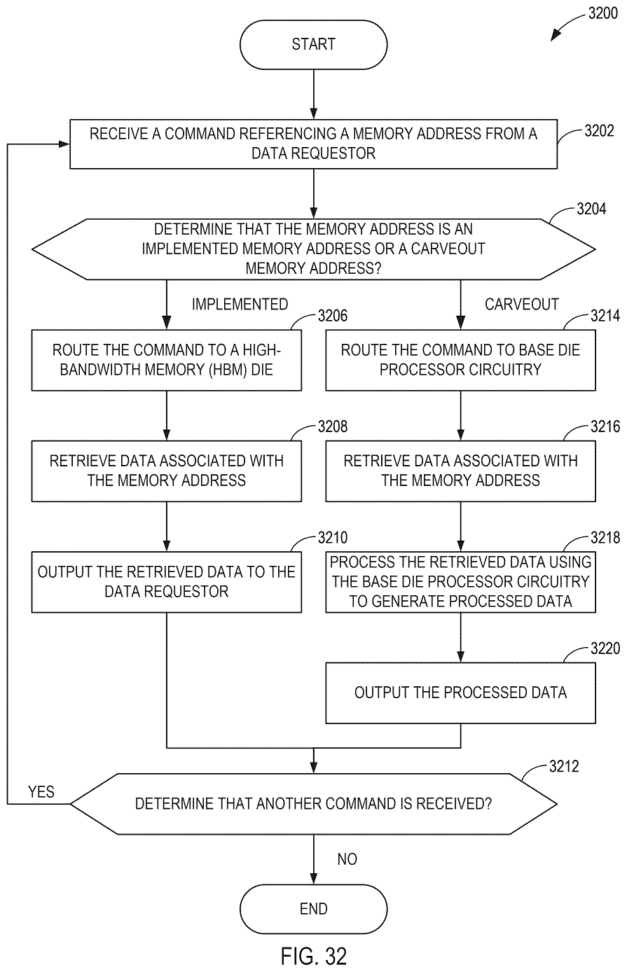

FIG. 32 is a flowchart 3200 representative of an example process that may be performed and/or implemented using (i) hardware logic or (ii) machine-readable instructions that may be executed by processor circuitry to implement the intelligent base die processing system 600 of FIG. 6 and/or the intelligent base die processing system 2900 of FIG. 29 to execute near-memory computing. Although the flowchart 3200 may be discussed in connection with one of the intelligent base die processing systems 600, 2900 of FIGS. 6 and 29, the flowchart 3200 may also be applicable to any other one(s) of the intelligent base die processing systems 600, 2900 of FIGS. 6 and 29. Additionally or alternatively, block(s) of the flowchart 3200 of FIG. 32 may be representative of state(s) of one or more hardware-implemented state machines, algorithm(s) that may be implemented by hardware alone such as an ASIC, etc., and/or any combination(s) thereof.

The flowchart 3200 of FIG. 32 begins at block 3202, at which the intelligent base die processing system 600, 2900 of FIGS. 6 and/or 29 may receive a command referencing a memory address from a data requestor. For example, the system physical interface 716 may receive a memory command from a data requestor, such as the accelerator 202. The memory command may reference an implemented memory address or a carved out memory address.

At block 3204, the intelligent base die processing system 600, 2900 may determine whether the memory address is an implemented memory address or a carveout memory address. For example, the system physical interface 716 may determine that the memory address referenced by the received command is an implemented memory address because the memory address is not in the base die BAR shown in FIG. 10. In another example, the system physical interface 716 may determine that the memory address referenced by the received command is a carveout memory address because the memory address is in the base die BAR shown in FIG. 10.

If, at block 3204, the intelligent base die processing system 600, 2900 determines that the memory address is an implemented memory address, control proceeds to block 3206. At block 3206, the intelligent base die processing system 600, 2900 may route the command to a high-bandwidth memory (HBM) die. For example, the system physical interface 716 may provide the memory address to the HBM controller 720 via the crossbar 718. The HBM controller 720 may provide, via a corresponding one of the pseudo channel physical interface 712, 714, the memory address to the bank control logic 302 of the HBM dies 216 to effectuate data retrieval.

At block 3208, the intelligent base die processing system 600, 2900 may retrieve data associated with the memory address. For example, the HBM dies 216 may output data, which is read from a physical memory address corresponding to the memory address, onto the corresponding one of the pseudo channel physical interface 712, 714. The HBM controller 720 may receive the retrieved data from the corresponding one of the pseudo channel physical interface 712, 714.

At block 3210, the intelligent base die processing system 600, 2900 may output the retrieved data to the data requestor. For example, the HBM controller 720 may provide the retrieved data to the system physical interface 716 via the crossbar 718. The system physical interface 716 may output the retrieved data to the accelerator 202. After outputting the retrieved data to the data requestor at block 3210, control proceeds to block 3212.

If, at block 3204, the intelligent base die processing system 600, 2900 determines that the memory address is a carveout memory address, control proceeds to block 3214. At block 3214, the intelligent base die processing system 600, 2900 may route the command to base die processor circuitry. For example, the system physical interface 716 may provide the memory address referenced by the received command to the DMA-XPOSE component 706. The DMA-XPOSE component 706 may provide, via a corresponding one of the pseudo channel physical interface 712, 714, the memory address to the bank control logic 302 of the HBM dies 216 to effectuate data retrieval.

At block 3216, the intelligent base die processing system 600, 2900 may retrieve data associated with the memory address. For example, the HBM dies 216 may output data, which is read from a physical memory address corresponding to the memory address, onto the corresponding one of the pseudo channel physical interface 712, 714. The corresponding one of the pseudo channel physical interface 712, 714 may store the data in the TCM 708.

At block 3218, the intelligent base die processing system 600, 2900 may process the retrieved data using the base die processor circuitry to generate processed data. For example, the processor 710 may process the data stored in the TCM 708 to generate processed data as described herein.

At block 3220, the intelligent base die processing system 600, 2900 may output the processed data. For example, the processor 710 may write the processed data back into the TCM 708 which, in turn, may write the data back into the HBM dies 606, 608. In another example, the processor 710 may write the processed data back into the TCM 708 which, in turn, may output the processed data to the accelerator 202 via the crossbar 718 and the system physical interface 716.

After outputting the processed data at block 3220, control proceeds to block 3212. At block 3212, the intelligent base die processing system 600, 2900 may determine whether another command is received. For example, the system physical interface 716 may determine that another command referencing a memory address has been received. If, at block 3220, the intelligent base die processing system 600, 2900 determines that another command is received, control returns to block 3202. Otherwise the flowchart 3200 of FIG. 32 concludes.

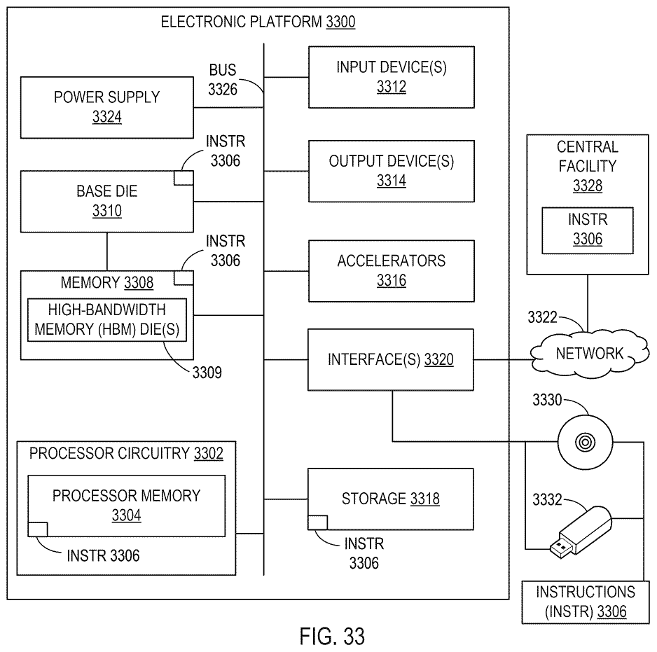

FIG. 33 is an example implementation of an electronic platform 3300 structured to execute the process of FIG. 32 to implement an intelligent base die processing system, such as the intelligent base die processing system 600 of FIG. 6 and/or the intelligent base die processing system 2900 of FIG. 29. It should be appreciated that FIG. 33 is intended neither to be a description of necessary components for an electronic and/or computing device to implement the intelligent base die processing system 600, 2900, in accordance with the techniques described herein, nor a comprehensive depiction.

The electronic platform 3300 of this example may be an electronic device, such as a handset device (e.g., a cellular network device, a smartphone, etc.), a desktop computer, a laptop computer, a tablet computer, a server (e.g., a computer server, a blade server, a rack-mounted server, etc.), a wearable device (e.g., an augmented reality and/or virtual reality (AR/VR) device, a heads-up display (HUD) device, a fitness tracker, a smartwatch, smart glasses, smart goggles, a workstation, or any other type of computing and/or electronic device.

The electronic platform 3300 of the illustrated example includes processor circuitry 3302, which may be implemented by one or more programmable processors, one or more hardware-implemented state machines, one or more ASICs, etc., and/or any combination(s) thereof. For example, the one or more programmable processors may include one or more CPUs, one or more DSPs, one or more FPGAs, one or more GPUs, etc., and/or any combination(s) thereof. The processor circuitry 3302 includes processor memory 3304, which may be volatile memory, such as random-access memory (RAM) of any type.

The processor circuitry 3302 may execute machine-readable instructions 3306 (identified by INSTRUCTIONS), which are stored in the processor memory 3304, to implement the intelligent base die processing system 600, 2900 of FIGS. 6 and/or 29 at least in part. The machine-readable instructions 3306 may include data representative of computer-executable and/or machine-executable instructions implementing techniques that operate according to the techniques described herein. For example, the machine-readable instructions 3306 may include data (e.g., code, embedded software (e.g., firmware), software, etc.) representative of the flowchart 3200 of FIG. 32, or portion(s) thereof.

The electronic platform 3300 includes memory 3308, which may include the instructions 3306. The memory 3308 of this example may be controlled by a base die 3310. For example, the base die 3310 may control reads, writes, and/or, more generally, access(es) to the memory 3308 by other component(s) of the electronic platform 3300. In some embodiments, the base die 3310 may implement the base die 602 of FIG. 6 and/or the base die 2902 of FIG. 29.

The memory 3308 of this example may be implemented by volatile memory, non-volatile memory, etc., and/or any combination(s) thereof. For example, the volatile memory may include static random-access memory (SRAM), dynamic random-access memory (DRAM), cache memory (e.g., Level 1 (L1) cache memory, Level 2 (L2) cache memory, Level 3 (L3) cache memory, etc.), etc., and/or any combination(s) thereof. In some embodiments, the non-volatile memory may include Flash memory, electrically erasable programmable read-only memory (EEPROM), magnetoresistive random-access memory (MRAM), ferroelectric random-access memory (FeRAM, F-RAM, or FRAM), etc., and/or any combination(s) thereof. In this example, the memory 3308 implements HBM die(s) 3309. The HBM dies 3309 may be implemented by the HBM dies 216 of FIGS. 2 and/or 3, the HBM dies 606, 608 of FIG. 6, and/or the HBM dies 2906, 2908, 2909 of FIG. 29.

The electronic platform 3300 includes input device(s) 3312 to enable data and/or commands to be entered into the processor circuitry 3302. For example, the input device(s) 3312 may include an audio sensor, a camera (e.g., a still camera, a video camera, etc.), a keyboard, a microphone, a mouse, a touchscreen, a voice recognition system, etc., and/or any combination(s) thereof.

The electronic platform 3300 includes output device(s) 3314 to convey, display, and/or present information to a user (e.g., a human user, a machine user, etc.). For example, the output device(s) 3314 may include one or more display devices, speakers, etc. The one or more display devices may include an augmented reality (AR) and/or virtual reality (VR) display, a liquid crystal display (LCD), a light-emitting diode (LED) display, an organic light-emitting diode (OLED) display, a quantum dot (QLED) display, a thin-film transistor (TFT) LCD, a touchscreen, etc., and/or any combination(s) thereof. The output device(s) 3314 can be used, among other things, to generate, launch, and/or present a user interface. For example, the user interface may be generated and/or implemented by the output device(s) 3314 for visual presentation of output and speakers or other sound generating devices for audible presentation of output.

The electronic platform 3300 includes accelerators 3316, which are hardware devices to which the processor circuitry 3302 may offload compute tasks to accelerate their processing. For example, the accelerators 3316 may include artificial intelligence/machine-learning (AI/ML) processors, ASICs, FPGAs, graphics processing units (GPUs), neural network (NN) processors, systems-on-chip (SoCs), vision processing units (VPUs), etc., and/or any combination(s) thereof. In some embodiments, the accelerators 3316 may implement the accelerator 202 of FIG. 2.

The electronic platform 3300 includes storage 3318 to record and/or control access to data, such as the machine-readable instructions 3306. The storage 3318 may be implemented by one or more mass storage disks or devices, such as hard disk drives (HDDs), solid state drives (SSDs), etc., and/or any combination(s) thereof.

The electronic platform 3300 includes interface(s) 3320 to effectuate exchange of data with external devices (e.g., computing and/or electronic devices of any kind) via a network 3322. The interface(s) 3320 of the illustrated example may be implemented by an interface device, such as network interface circuitry (e.g., a network interface card (NIC), a smart NIC, etc.), a gateway, a router, a switch, etc., and/or any combination(s) thereof. The interface(s) 3320 may implement any type of communication interface, such as BLUETOOTH®, a cellular telephone system (e.g., a 4G LTE interface, a 5G interface, a future generation 6G interface, etc.), an Ethernet interface, a near-field communication (NFC) interface, an optical disc interface (e.g., a Blu-ray disc drive, a Compact Disk (CD) drive, a Digital Versatile Disk (DVD) drive, etc.), an optical fiber interface, a satellite interface (e.g., a BLOS satellite interface, a LOS satellite interface, etc.), a Universal Serial Bus (USB) interface (e.g., USB Type-A, USB Type-B, USB TYPE-C™ or USB-C™, etc.), etc., and/or any combination(s) thereof.

The electronic platform 3300 includes a power supply 3324 to store energy and provide power to components of the electronic platform 3300. The power supply 3324 may be implemented by a power converter, such as an alternating current-to-direct-current (AC/DC) power converter, a direct current-to-direct current (DC/DC) power converter, etc., and/or any combination(s) thereof. For example, the power supply 3324 may be powered by an external power source, such as an alternating current (AC) power source (e.g., an electrical grid), a direct current (DC) power source (e.g., a battery, a battery backup system, etc.), etc., and the power supply 3324 may convert the AC input or the DC input into a suitable voltage for use by the electronic platform 3300. In some examples, the power supply 3324 may be a limited duration power source, such as a battery (e.g., a rechargeable battery such as a lithium-ion battery).

Component(s) of the electronic platform 3300 may be in communication with one(s) of each other via a bus 3326. For example, the bus 3326 may be any type of computing and/or electrical bus, such as an I2C bus, a PCI bus, a PCIe bus, a SPI bus, a UCIe bus, and/or the like.

The network 3322 may be implemented by any wired and/or wireless network(s) such as one or more cellular networks (e.g., 4G LTE cellular networks, 5G cellular networks, future generation 6G cellular networks, etc.), one or more data buses, one or more local area networks (LANs), one or more optical fiber networks, one or more private networks, one or more public networks, one or more wireless local area networks (WLANs), etc., and/or any combination(s) thereof. For example, the network 3322 may be the Internet, but any other type of private and/or public network is contemplated.

The network 3322 of the illustrated example facilitates communication between the interface(s) 3320 and a central facility 3328. The central facility 3328 in this example may be an entity associated with one or more servers, such as one or more physical hardware servers and/or virtualizations of the one or more physical hardware servers. For example, the central facility 3328 may be implemented by a public cloud provider, a private cloud provider, etc., and/or any combination(s) thereof. In this example, the central facility 3328 may compile, generate, update, etc., the machine-readable instructions 3306 and store the machine-readable instructions 3306 for access (e.g., download) via the network 3322. For example, the electronic platform 3300 may transmit a request, via the interface(s) 3320, to the central facility 3328 for the machine-readable instructions 3306 and receive the machine-readable instructions 3306 from the central facility 3328 via the network 3322 in response to the request.

Additionally or alternatively, the interface(s) 3320 may receive the machine-readable instructions 3306 via non-transitory machine-readable storage media, such as an optical disc 3330 (e.g., a Blu-ray disc, a CD, a DVD, etc.) or any other type of removable non-transitory machine-readable storage media such as a USB drive 3332. For example, the optical disc 3330 and/or the USB drive 3332 may store the machine-readable instructions 3306 thereon and provide the machine-readable instructions 3306 to the electronic platform 3300 via the interface(s) 3320.

Techniques operating according to the principles described herein may be implemented in any suitable manner. The processing and decision blocks of the flowchart(s) above represent steps and acts that may be included in algorithms that carry out these various processes. Algorithms derived from these process(es) may be implemented as software integrated with and directing the operation of one or more single- or multi-purpose processors, may be implemented as functionally equivalent circuits such as a DSP circuit or an ASIC, or may be implemented in any other suitable manner. It should be appreciated that the flowchart(s) included herein do(es) not depict the syntax or operation of any particular circuit or of any particular programming language or type of programming language. Rather, the flowchart(s) illustrate the functional information one skilled in the art may use to fabricate circuits or to implement computer software algorithms to perform the processing of a particular apparatus carrying out the types of techniques described herein. For example, the flowchart(s), or portion(s) thereof, may be implemented by hardware alone (e.g., one or more analog or digital circuits, one or more hardware-implemented state machines, etc., and/or any combination(s) thereof) that is configured or structured to carry out the various processes of the flowcharts. In another example, the flowchart(s), or portion(s) thereof, may be implemented by machine-executable instructions (e.g., machine-readable instructions, computer-readable instructions, computer-executable instructions, etc.) that, when executed by one or more single- or multi-purpose processors, carry out the various process(es) of the flowchart(s). It should also be appreciated that, unless otherwise indicated herein, the particular sequence of steps and/or acts described in each flowchart is merely illustrative of the algorithms that may be implemented and can be varied in implementations and embodiments of the principles described herein.

Accordingly, in some embodiments, the techniques described herein may be embodied in machine-executable instructions implemented as software, including as application software, system software, firmware, middleware, embedded code, or any other suitable type of computer code. Such machine-executable instructions may be generated, written, etc., using any of a number of suitable programming languages and/or programming or scripting tools, and also may be compiled as executable machine language code or intermediate code that is executed on a framework, virtual machine, or container.

Machine-executable instructions (e.g., processor-executable instructions) implementing the techniques described herein may, in some embodiments, be encoded on one or more computer-readable media, machine-readable media, etc., to provide functionality to the media. Computer-readable media, machine-readable media, etc., include magnetic media such as a hard disk drive, optical media such as a CD or a DVD, a persistent or non-persistent solid-state memory (e.g., Flash memory, Magnetic RAM, etc.), or any other suitable storage media. Such a computer-readable medium, a machine-readable medium, etc., may be implemented in any suitable manner.

Embodiments have been described where the techniques are implemented in circuitry and/or machine-executable instructions. It should be appreciated that some embodiments may be in the form of a method, of which at least one example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

As used herein, the terms “computer-readable media” (also called “computer-readable storage media”), “computer-readable medium” (also called “computer-readable storage medium”), “machine-readable media” (also called “machine-readable storage media”), and “machine-readable medium” (also called “machine-readable storage medium”) refer to tangible storage media. Tangible storage media are non-transitory and have at least one physical, structural component. In a “computer-readable medium” and “machine-readable medium” as used herein, at least one physical, structural component has at least one physical property that may be altered in some way during a process of creating the medium with embedded information, a process of recording information thereon, or any other process of encoding the medium with information. For example, a magnetization state of a portion of a physical structure of a computer-readable medium, a machine-readable medium, etc., may be altered during a recording process.

Further, some techniques described above comprise acts of storing information (e.g., data and/or instructions) in certain ways for use by these techniques. In some implementations of these techniques—such as implementations where the techniques are implemented as machine-executable instructions—the information may be encoded on a computer-readable storage medium, a machine-readable storage medium, etc. Where specific structures are described herein as advantageous formats in which to store this information, these structures may be used to impart a physical organization of the information when encoded on the storage medium. These advantageous structures may then provide functionality to the storage medium by affecting operations of one or more processors interacting with the information; for example, by increasing the efficiency of computer operations performed by the processor(s).

The phrase “and/or,” as used herein in the specification and in the claims, should be understood to mean “either or both,” of the elements so conjoined, e.g., elements that are conjunctively present in some cases and disjunctively present in other cases. Multiple elements listed with “and/or” should be construed in the same fashion, e.g., “one or more” of the elements so conjoined. Other elements may optionally be present other than the elements specifically identified by the “and/or” clause, whether related or unrelated to those elements specifically identified. Thus, as a non-limiting example, a reference to “A and/or B,” when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

The indefinite articles “a” and “an,” as used herein in the specification and in the claims, unless clearly indicated to the contrary, should be understood to mean “at least one.”

As used herein in the specification and in the claims, the phrase, “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently, “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

Also, the phraseology and terminology used herein is for the purpose of description and should not be regarded as limiting. The use of “including,” “comprising,” “having,” “containing,” “involving,” and variations thereof herein, is meant to encompass the items listed thereafter and equivalents thereof as well as additional items.

All definitions, as defined and used herein, should be understood to control over dictionary definitions, definitions in documents incorporated by reference, and/or ordinary meanings of the defined terms.

Various aspects of the embodiments described above may be used alone, in combination, or in a variety of arrangements not specifically discussed in the embodiments described in the foregoing and is therefore not limited in its application to the details and arrangement of components set forth in the foregoing description or illustrated in the drawings. For example, aspects described in one embodiment may be combined in any manner with aspects described in other embodiments.

Accordingly, having thus described several aspects of at least one embodiment, it is to be appreciated that various alterations, modifications, and improvements will readily occur to those skilled in the art. Such alterations, modifications, and improvements are intended to be part of this disclosure and are intended to be within the spirit and scope of the principles described herein. Accordingly, the foregoing description and drawings are by way of example only.

1. A system for executing compute-near-memory operations by using high-bandwidth memory (HBM), comprising:
a memory stack comprising multiple HBM dies, each HBM die comprising an array of banks addressable by a plurality of implemented memory addresses, wherein the plurality of implemented memory addresses comprise a first subset of an available range of memory addresses; and
a base die coupled to the memory stack, the base die comprising processor circuitry, the processor circuitry comprising at least one hardware processor configured to execute the compute-near-memory operations on data associated with a plurality of carveout memory addresses, wherein the plurality of carveout memory addresses comprise a second subset of the available range of memory addresses, wherein the processor circuitry is configured to:
receive, by using an external interface, a command referencing a memory address;
retrieve, by using a memory interface configured to drive the HBM dies, the data from the memory stack for storage in first memory accessible by the at least one hardware processor when the memory address is associated with the plurality of carveout memory addresses;
process, by using the at least one hardware processor, the retrieved data to generate processed data; and
output the processed data.

2. The system of claim 1, wherein the processor circuitry is configured to:
route, by using the memory interface, the command to the HBM dies when the memory address is associated with the plurality of implemented memory addresses.

3. The system of claim 2, wherein the processor circuitry comprises:
a crossbar switch coupled to the external interface; and
an HBM controller coupled to the crossbar switch and the memory interface, wherein the processor circuitry is configured to route the command to the HBM dies by:
routing the command from the external interface to the crossbar switch;
routing the command from the crossbar switch to the HBM controller; and
routing, by using the memory interface, the command from the HBM controller to the HBM dies.

4. (canceled)

5. (canceled)

6. (canceled)

7. (canceled)

8. The system of claim 1, wherein the processor circuitry is configured to output the processed data by storing the processed data in the HBM dies.

9. The system of claim 1, wherein the processor circuitry is configured to output the processed data by transmitting, by using the external interface, the processed data to an accelerator coupled to the base die.

10. The system of claim 9, further comprising the accelerator, wherein the accelerator is configured to execute at least one artificial intelligence and/or machine learning model.

11. (canceled)

12. (canceled)

13. (canceled)

14. (canceled)

15. (canceled)

16. The system of claim 1, further comprising an external memory controller separate from the base die, wherein the base die selectively passes memory commands from the external memory controller to the memory stack.

17. (canceled)

18. (canceled)

19. (canceled)

20. The system of claim 1, wherein the memory stack is coupled to the base die via through-silicon vias (TSVs).

21. The system of claim 20, wherein the TSVs comprise a first plurality of TSVs disposed on a first side of the memory stack and a second plurality of TSVs disposed on a second side of the memory stack, different from the first side.

22. The system of claim 20, wherein the TSVs comprise a first plurality of TSVs disposed in respective first areas of the memory stack and a second plurality of TSVs disposed in respective second areas of the memory stack, different from the first areas.

23. The system of claim 20, wherein at least some of the TSVs are coupled together using microbumps.

24. (canceled)

25. (canceled)

26. (canceled)

27. (canceled)

28. (canceled)

29. (canceled)

30. (canceled)

31. (canceled)

32. (canceled)

33. (canceled)

34. (canceled)

35. (canceled)

36. (canceled)

37. A base die for executing compute-near-memory operations, comprising:
at least one system interface configured to receive a command referencing a memory address;
at least one memory interface configured to:
drive at least one high-bandwidth memory (HBM) die of an HBM stack, the HBM stack addressable by a first plurality of implemented memory addresses, the first plurality of implemented memory addresses being a first portion of available memory addresses; and
retrieve data from the at least one HBM die in response to a determination that the command references one of a second plurality of carveout memory addresses, the second plurality of carveout memory addresses being a second portion of the available memory addresses; and
at least one hardware processor configured to:
execute the compute-near-memory operations on the retrieved data to generate processed data; and
output the processed data.

38. (canceled)

39. (canceled)

40. The base die of claim 37, wherein the base die comprises an HBM controller, and the at least one memory interface comprises:
a first memory interface associated with a first pseudo channel of the HBM stack, wherein
the HBM controller is configured to route, by using the first memory interface, the command to the first pseudo channel when the memory address references the first pseudo channel.

41. The base die of claim 40, wherein the at least one memory interface comprises:
a second memory interface associated with a second pseudo channel of the HBM stack, wherein
the HBM controller is configured to route, by using the second memory interface, the command to the second pseudo channel when the memory address references the second pseudo channel.

42. The base die of claim 37, wherein the base die comprises:
first memory coupled to the at least one hardware processor; and
a direct memory access (DMA) controller coupled to the at least one system interface, wherein
the at least one system interface is configured to route the command to the DMA controller, and
the DMA controller is configured to route, by using the at least one memory interface, the command to the at least one HBM die to cause the at least one HBM die to output the data for storage in the first memory.

43. (canceled)

44. (canceled)

45. The base die of claim 37, further comprising tightly coupled memory coupled to the at least one hardware processor, and the tightly coupled memory is configured to store the data retrieved from the least one HBM die.

46. (canceled)

47. (canceled)

48. (canceled)

49. (canceled)

50. (canceled)

51. The base die of claim 37, wherein the at least one hardware processor comprises a first hardware processor and a second hardware processor, and further comprising:
a crossbar switch coupled to the first hardware processor and the second hardware processor such that at least the first hardware processor and the second hardware processor are interconnected by the crossbar switch.

52. The base die of claim 37, further comprising:
first processor circuitry comprising the at least one system interface, the at least one memory interface, and the at least one hardware processor;
second processor circuitry; and
a network-on-chip coupled to the first processor circuitry and the second processor circuitry such that the first processor circuitry and the second processor circuitry are interconnected by the network-on-chip.

53. (canceled)

54. (canceled)

55. (canceled)

56. (canceled)

57. (canceled)

58. (canceled)

59. (canceled)

60. The base die of claim 37, further comprising a circular first-in, first-out buffer for storing interrupt status entries.

61. (canceled)

62. The base die of claim 37, wherein the at least one HBM die comprises one or more registers, and the one or more registers are repurposed as an interrupt mechanism to indicate completion of compute operations by the at least one hardware processor.

63. The base die of claim 37, wherein the at least one HBM die comprises a first HBM die having a first register and a second HBM die having a second register, and the at least one hardware processor is configured to combine at least the first register and the second register into a wider control register.

64. (canceled)

65. (canceled)

66. (canceled)

67. The base die of claim 37, further comprising root-of-trust hardware embedded in the base die to authenticate code and protect programmable processing logic from unauthorized access.

68. The base die of claim 37, wherein the at least one hardware processor is configured to execute code to implement one or more Open Neural Network Exchange (ONNX) operators to execute at least one artificial intelligence and/or machine learning model.

69. A method for near-memory computing by using a memory stack including at least one high-bandwidth memory (HBM) die and a base die, the at least one HBM die associated with a plurality of memory addresses, the at least one HBM die having at least one bank addressable by a first portion of the plurality of memory addresses, the base die including at least one memory and at least one hardware processor, the method comprising:
by using the base die to perform:
receiving a command referencing a memory address;
determining that the memory address references a second portion of the plurality of memory addresses;
retrieving data from the at least one HBM die for storage in the at least one memory; and
processing, by using the at least one hardware processor, the data to generate processed data for output to an external device.

70. (canceled)

71. (canceled)

72. (canceled)

73. (canceled)

74. (canceled)

75. (canceled)

76. (canceled)

77. (canceled)

78. (canceled)

79. The method of claim 69, wherein receiving the command comprises receiving, by using an external interface, the command from an external accelerator system comprising at least one accelerator die.

80. (canceled)

81. (canceled)

82. (canceled)

83. The method of claim 69, wherein the base die comprises global signal handler circuitry, and further comprising outputting, by using the global signal handler circuitry, global group signals to an external device, the global group signals comprising at least one signal representative of a temperature measurement.

84. The method of claim 69, wherein the base die comprises global signal handler circuitry, and further comprising outputting, by using the global signal handler circuitry, global group signals to an external device, the global group signals comprising TEMP[1:0] signal lines.

85. The method of claim 84, further comprising repurposing, by using the base die, the TEMP[1:0] signal lines as an interrupt mechanism to indicate completion of compute operations on the base die.

86. (canceled)

87. The method of claim 69, further comprising notifying, by using an interrupt mechanism, an external interface that the at least one hardware processor has completed a compute-near-memory operation, wherein the interrupt mechanism comprises one of a dedicated sideband signal and repurposed reserved bits of an HBM signal specification.

88. (canceled)

89. (canceled)

90. The method of claim 69, further comprising establishing, by using the at least one hardware processor, the second portion of the plurality of memory addresses by generating a set base die block address range command.

91. The method of claim 69, further comprising performing, by using the at least one hardware processor, page stream sorting to manage open memory pages in the at least one HBM die.

92. The method of claim 69, wherein receiving the command comprises performing analog switching to minimize pass-through latency for memory commands issued by an external accelerator.

93. (canceled)

94. (canceled)
